(19) United States
(12) Patent Application Publication
(10) Pub. No.: US 2024/0250065 A1
(43) Pub. Date: Jul. 25, 2024

(54) DISPLAY DEVICE

(71) Applicant: LG ELECTRONICS INC., Seoul (KR)

(72) Inventors: Chilkeun PARK, Seoul (KR); Byoungkwon CHO, Seoul (KR); Wonseok CHOI, Seoul (KR); Wonjae CHANG, Seoul (KR)

(73) Assignee: LG ELECTRONICS INC., Seoul (KR)

(21) Appl. No.: 18/290,995

(22) PCT Filed: Jul. 21, 2021
(86) PCT No.: PCT/KR2021/009371

§ 371 Date: Jan. 22, 2024

(51) Int. Cl. H01L 25/065; H01L 27/12; H01L 33/62

(52) U.S. Cl. CPC H01L 25/0652; H01L 27/124; H01L 33/62

(57) ABSTRACT

The display device can include a substrate, a barrier rib having an assembly hole on the substrate, a semiconductor light emitting device in the assembly hole, and a first connection part disposed in the assembly hole and on the barrier rib and electrically connected to a side surface of the semiconductor light emitting device. In the embodiment, maximum luminance can always be obtained regardless of whether the assembling wirings disposed on the substrate are disposed on the same layer or different layers, and each pixel has constant luminance, thereby improving image quality due to luminance uniformity.

### TECHNICAL FIELD

The embodiment relates to a display device.

### BACKGROUND ART

A display device displays high-definition image using self-emissive element such as a light emitting diode as a light source for a pixel. The light emitting diode exhibits excellent durability even under harsh environmental conditions and is capable of long lifespan and high luminance, so that that that it is attracting attention as a light source for next-generation display devices.

Recently, research is in progress to manufacture ultra-small light emitting diodes using highly a material having reliable inorganic crystal structure and dispose them on the panel of a display device (hereinafter referred to as “display panel”) to use them as a light source for a next-generation pixel.

This display device is expanding beyond a flat display into various forms such as a flexible display, a foldable display, a stretchable display, and a rollable display.

In order to realize high resolution, the size of the pixel is gradually becoming smaller, and numerous light emitting devices must be aligned in the smaller pixel, so that that research on the manufacture of ultra-small light emitting diodes as small as micro- or nano-scale is actively taking place.

Typically, a display panel contains millions to tens of millions of pixels. Accordingly, because it is very difficult to align at least one light emitting device in each of tens of millions of small pixels, various studies on ways to align light emitting devices in the display panel are being actively conducted recently.

As the size of light emitting devices becomes smaller, transferring these light emitting devices onto a substrate is becoming a very important problem to solve. Transfer technologies that have been recently developed include the pick and place process, laser lift-off method, self-assembly method, etc. In particular, the self-assembly method that transfers light emitting devices onto a substrate using a magnetic body (or magnet) has recently been in the spotlight.

In the self-assembly method, numerous light emitting devices are dropped into a bath containing water, and the light emitting devices dropped into the water are moved according to the movement of the magnetic body, so that that the light emitting devices are aligned in each pixel.

However, even if the light emitting device is moved near the pixel due to the movement of the magnetic body, the light emitting device may not be aligned with the pixel because it is very light. Accordingly, assembling wirings are disposed on a substrate on which a plurality of pixels are defined in order to fix the light emitting devices to the pixels. A light emitting device is fixed to each pixel by a dielectrophoretic force formed by a voltage applied to a pair of assembling wiring.

Conventional assembling wirings are usually disposed in the same layer. However, as the pixel size gradually becomes smaller for higher resolution, the gap between the assembling wirings narrows, causing an electrical short.

To solve this problem, as shown in FIGS. 1 and 2, the assembling wiring 2 and 3 were disposed in different layers on the substrate 1.

Since the assembling wirings 2 and 3 are disposed in different layers, the electric field generated between the assembling wirings 2 and 3 is non-uniform, and the dielectrophoretic force is also non-uniform.

Accordingly, as shown in FIG. 1, the light emitting device 7 located in the assembly hole 6 is tilted to one side, and the light emitting device 7 does not electrically contact the assembling wiring 3. When the assembling wiring 3 is used as a wiring electrode, voltage is not supplied from the assembling wiring 3 to the light emitting device 7, so that there is a problem in which lighting defects of the light emitting device 7 occur.

In addition, as shown in FIG. 2, when the light emitting device 7 located in the assembly hole 6 is biased to one side, a space is secured between the light emitting device 7 and the barrier rib 5, and another light emitting device 8 is positioned in this space. Accordingly, the light emitting device 8 blocks the light emission of the light emitting device 7. In addition, there is a problem in that the post-process for emitting light of the light emitting device 7, that is, the electrical connection process, is difficult or defective due to the light emitting device 8, resulting in lighting defects of the light emitting device 7. In addition, the light emitting device 8 may not be used for light emission, which has the problem of increasing the manufacturing cost.

On the other hand, as in the related art, when the assembling wirings 2 and 3 are disposed in different layers and the assembling wiring 3 is used as the wiring electrode 3 for emitting light from the light emitting device 7, due to the bias of the light emitting device 7, the area where the light emitting device 7 contacts the wiring electrode 3 is different for each pixel. As the contact area between the light emitting device 7 and the wiring electrode 3 is different for each pixel, there is a problem in that luminance deviation occurs for each pixel and image quality deteriorates.

In addition, conventionally, even if the light emitting device 7 is positioned in the assembly hole 6, the entire lower surface of the light emitting device 7 is not in contact with the wiring electrode 3, so the luminance of the light emitting device 7, so that there was a limit to improving luminance of the light emitting device 7.

### DISCLOSURE

### Technical Problem

An object of the embodiment is to solve the foregoing and other problems.

Another object of the embodiment is to provide a display device that can minimize lighting defects.

Another object of the embodiment is to provide a display device that can reduce manufacturing costs.

Another object of the embodiment is to provide a display device that can improve image quality with uniform luminance of each pixel.

Another object of the embodiment is to provide a display device that can improve luminance.

The technical problems of the embodiment are not limited to those described in this item, and comprise those that can be understood through the description of the invention.

### Technical Solution

According to one aspect of the embodiment to achieve the above or other objects, a display device, comprising: a substrate; a barrier rib having an assembly hole on the substrate; a semiconductor light emitting device in the assembly hole; and a first connection part disposed in the assembly hole and on the barrier rib and electrically connected to a side surface of the semiconductor light emitting device.

The first connection part can comprise a conductive liquid photosensitive material.

The semiconductor light emitting device comprises: a first conductivity type semiconductor layer comprising a first-first conductivity type semiconductor layer and a first-second conductivity type semiconductor layer on the first-first conductivity type semiconductor layer; an active layer on the first conductive semiconductor layer; a second conductive semiconductor layer on the active layer; and a protective layer surrounding a side surface of the first-second conductivity type semiconductor layer, a side surface of the active layer, and a side surface of the second conductivity type semiconductor layer.

The first connection part can be in contact with the side surface of the first-first semiconductor light emitting device along a perimeter of a side surface of the first-first conductivity type semiconductor layer.

### Advantageous Effects

In the embodiment, maximum luminance can always be obtained regardless of whether the assembling wirings disposed on the substrate are disposed in the same layer or different layers, and each pixel has constant luminance, improving image quality due to luminance uniformity.

The assembling wirings 321 and 322 can be disposed in the same layer (FIGS. 13, 15, and 27) or can be disposed on different layers (FIG. 28). In an embodiment, a portion of the side surface of the semiconductor light emitting device 150, that is, the side surface of the first-first conductivity type semiconductor layer 151_1, can be exposed to the outside. When the semiconductor light emitting device 150 is assembled within the assembly hole 345, the first connection part 350 can be disposed within the assembly hole 345. The first connection part 350 can contact the side surface of the first-first conductivity type semiconductor layer 151_1 of the semiconductor light emitting device 150. Specifically, the first connection part 350 can be in contact with the side surface of the first-first conductivity type semiconductor layer 151_1 along a perimeter of a side surface of the first-first conductivity type semiconductor layer 151_1 of the semiconductor light emitting device 150. Therefore, since the entire area of the side surface of the first-first conductivity type semiconductor layer 151_1 is in contact with the first connection part 350, the contact area between the first-first conductivity type semiconductor layer 151_1 and the first connection part 350 is maximized, so that there is no current loss through the first connection part 350, and maximum luminance can be obtained from the semiconductor light emitting device 150. In addition, since the entire area of the side surface of the first-first conductivity type semiconductor layer 151_1 for each pixel is in contact with the first connection part 350, there is no luminance deviation between the luminance obtained from the semiconductor light emitting device 150 for each pixel, thereby improving image quality. For example, since the luminance corresponding to 255 gray levels is the same for all pixels, accurate gray level expression is possible at each pixel, thereby improving image quality.

When the assembling wirings 321 and 322 are disposed in different layers, the dielectrophoretic force can be non-uniform between the assembling wirings 321 and 322, so that the semiconductor light emitting device 150 located in the assembly hole 345 can be biased toward the second assembling wiring 322. In this way, even if the semiconductor light emitting device 150 is biased toward the second assembling wiring 322, the side surface of the first-first conductivity type semiconductor layer 151_1 of the semiconductor light emitting device 150 can be biased toward the second assembling wiring 322. The entire area can be in contact with the first connection part 350 disposed in the assembly hole 345. Accordingly, the luminance between each pixel (based on 2550 gray scale) can be the same regardless of whether the semiconductor light emitting device 150 is biased or not biased toward the second assembling wiring 322, so that there is no deviation in luminance between each pixel, thereby improving image quality.

In addition, regardless of whether the semiconductor light emitting device 150 is biased toward the second assembling wiring 322 or not, the side surface of the first-first conductivity type semiconductor layer 151_1 of the semiconductor light emitting device 150 can be electrically connected to the first connection part 350, so that there are no pixels that do not light up, thereby minimizing lighting defects.

In the embodiment, a structure in which the assembling wirings 321 and 322 are disposed in the same layer is possible, so that the semiconductor light emitting device 150 can be aligned in the correct position in the assembly hole 345 by the assembling wirings 321 and 322 disposed in the same layer. When the semiconductor light emitting device 150 is aligned in the correct position in the assembly hole 345, other semiconductor light emitting devices cannot be inserted into the assembly hole 345, so that the manufacturing cost can be lowered by reducing the number of semiconductor light emitting devices additionally assembled in the assembly hole 345.

Additional scope of applicability of the embodiments will become apparent from the detailed description below. However, since various changes and modifications within the spirit and scope of the embodiments can be clearly understood by those skilled in the art, the detailed description and specific embodiments, such as preferred embodiments, should be understood as being given by way of example only.

### DESCRIPTION OF DRAWINGS

FIG. 1 shows an example of misalignment of a conventional light emitting device.

FIG. 2 shows another example of misalignment of a conventional light emitting device.

FIG. 3 shows the living room of a house where a display device according to an embodiment is disposed.

FIG. 4 is a block diagram schematically showing a display device according to an embodiment.

FIG. 5 is a circuit diagram showing an example of the pixel of FIG. 4.

FIG. 6 is a plan view showing the display panel of FIG. 4 in detail.

FIG. 7 is an enlarged view of the first panel area in the display device of FIG. 3.

FIG. 8 is an enlarged view of area A2 in FIG. 7.

FIG. 9 is a diagram showing an example in which a light emitting device according to an embodiment is assembled on a substrate by a self-assembly method.

FIGS. 10 and 11 are diagrams showing an example in which a light emitting device according to an embodiment is transferred to a substrate by a transfer method.

FIG. 12 is a cross-sectional view schematically showing the display panel of FIG. 4.

FIG. 13 is a cross-sectional view showing a display device according to a first embodiment.

FIG. 14 is a cross-sectional view showing the semiconductor light emitting device of FIG. 13.

FIG. 15 is a cross-sectional view showing a display device according to a second embodiment.

FIGS. 16 to 26 are diagrams explaining the manufacturing method of the semiconductor light emitting device of FIG. 15.

FIG. 27 is a cross-sectional view showing a display device according to a third embodiment.

FIG. 28 is a cross-sectional view showing a display device according to a fourth embodiment.

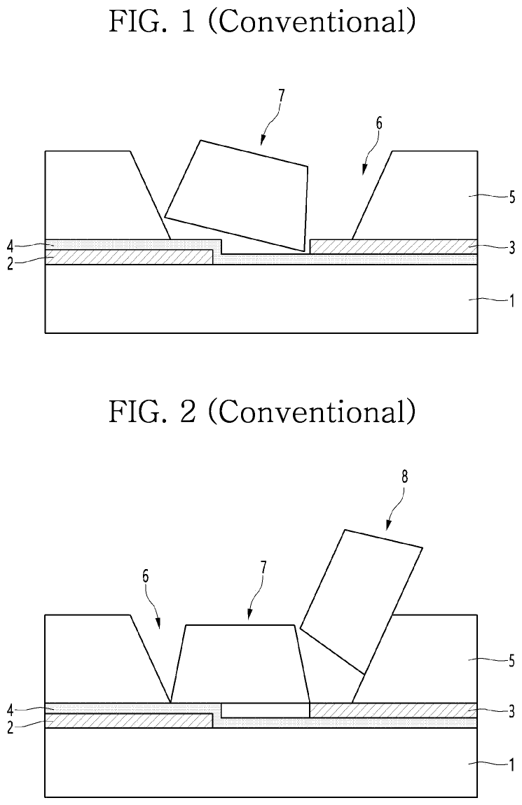

The size, shape, and dimensions of components shown in the drawings can be different from the actual ones. In addition, although the same components are shown in different sizes, shapes, and numbers between the drawings, this is only an example in the drawings, and the same components are shown in the same size, shape, and number across the drawings. You can have it.

### MODE FOR INVENTION

Hereinafter, the embodiments disclosed in the present specification will be described in detail with reference to the attached drawings, but identical or similar components will be given the same reference numbers regardless of the reference numerals, and duplicate descriptions thereof will be omitted. The suffixes ‘module’ and ‘unit’ for components used in the following description are given or used interchangeably in consideration of ease of specification preparation, and do not have distinct meanings or roles in themselves. Additionally, the attached drawings are intended to facilitate easy understanding of the embodiments disclosed in this specification, and the technical idea disclosed in this specification is not limited by the attached drawings. Additionally, when a component such as a layer, region or substrate is referred to as being ‘on’ another component, this means that there can be either directly on the other component or be other intermediate components in therebetween.

The display device described in this specification comprise a mobile phone, a smart phone, a laptop computer, a digital broadcasting terminal, a personal digital assistant (PDA), a portable multimedia player (PMP), a navigation, a slate personal computer (PC), a tablet PC, an ultra-book, a digital TV, a desktop computer, etc. However, the configuration according to the embodiment described in this specification can be applied to a device capable of displaying even if it is a new product type that is developed in the future.

Hereinafter, a light emitting device according to an embodiment and a display device including the same will be described.

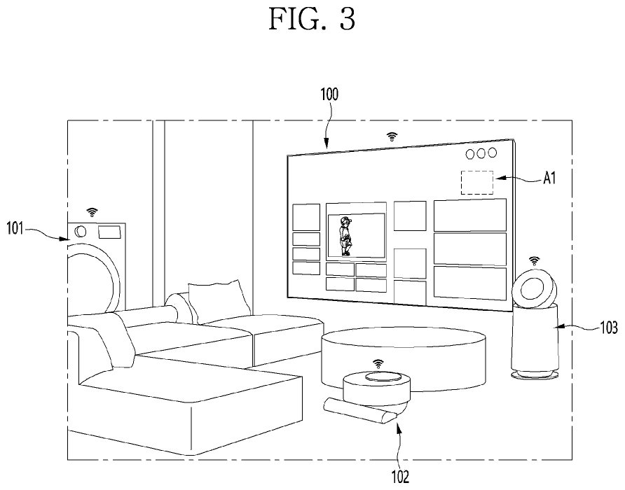

FIG. 3 shows the living room of a house where a display device according to an embodiment is disposed.

Referring to FIG. 3, the display device 100 of the embodiment can display the status of various electronic products such as a washing machine 101, a robot cleaner 102, and an air purifier 103, can communicate with each electronic product based on an internet of things (IOT), can control each electronic product based on the user's setting data.

The display device 100 according to the embodiment can comprise a flexible display manufactured on a thin and flexible substrate. The flexible display can bend or curl like paper while maintaining the characteristics of existing flat displays.

In the flexible display, visual information can be implemented by independently controlling the light emission of unit pixels disposed in a matrix form. A unit pixel refers to the minimum unit for implementing one color. The unit pixel of the flexible display can be implemented by a light emitting device. In the embodiment, the light emitting device can be a micro-LED or nano-LED, but is not limited thereto.

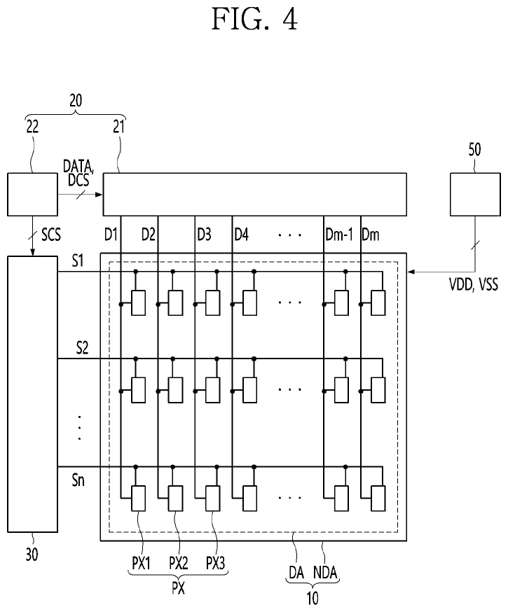

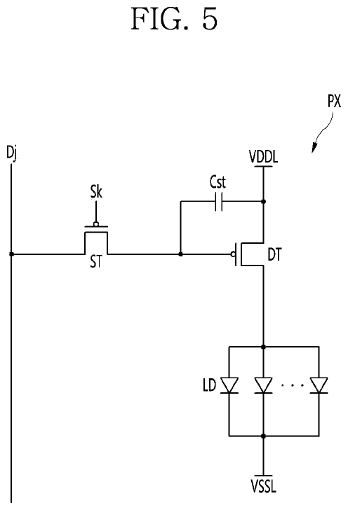

FIG. 4 is a block diagram schematically showing a display device according to an embodiment, and FIG. 5 is a circuit diagram showing an example of the pixel of FIG. 4.

Referring to FIGS. 4 and 5, a display device according to an embodiment can comprise a display panel 10, a driving circuit 20, a scan driver 30, and a power supply circuit 50.

The display device 100 of the embodiment can drive the light emitting device in an active matrix (AM) method or a passive matrix (PM) method.

The driving circuit 20 can comprise a data driving device 21 and a timing controller 22.

The display panel 10 can be rectangular, but is not limited thereto. That is, the display panel 10 can be formed in a circular or oval shape. At least one side of the display panel 10 can be bent to a predetermined curvature.

The display panel 10 can be divided into a display area DA and a non-display area NDA disposed around the display area DA. The display area DA is an area where pixels PX can be formed to display an image. The display panel 10 can comprise data lines (D1 to Dm, m is an integer greater than 2), scan lines (S1 to Sn, n is an integer greater than 2) that intersect the data lines D1 to Dm, a high potential voltage line supplied with high potential voltage, a low potential voltage line supplied with low potential voltage, and pixels PX connected to the data lines D1 to Dm and the scan lines S1 to Sn.

Each of the pixels PX can comprise a first sub-pixel PX1, a second sub-pixel PX2, and a third sub-pixel PX3. The first sub-pixel PX1 can emit a first color light of a first main wavelength, the second sub-pixel PX2 can emit a second color light of a second main wavelength, and the third sub-pixel PX3 can emit a third color light of a third main wavelength. The first color light can be red light, the second color light can be green light, and the third color light can be blue light, but are not limited thereto. Additionally, in FIG. 4, it is illustrated that each of the pixels PX can comprise three sub-pixels, but is not limited thereto. That is, each pixel PX can comprise four or more sub-pixels.

The first sub-pixel PX1, the second sub-pixel PX2, and the third sub-pixel PX3 each can be connected to at least one of the data lines D1 to Dm, at least one of the scan lines S1 to Sn, and the high potential voltage line. As shown in FIG. 5, the first sub-pixel PX1 can comprise light emitting devices LD, a plurality of transistors for supplying current to the light emitting devices LD, and at least one capacitor Cst.

Although not shown in the drawing, each of the first sub-pixel PX1, the second sub-pixel PX2, and the third sub-pixel PX3 can comprise only one light emitting device LD and at least one capacitor Cst.

Each of the light emitting devices LD can be a semiconductor light emitting diode comprising a first electrode, a plurality of conductivity type semiconductor layers, and a second electrode. Here, the first electrode can be an anode electrode and the second electrode can be a cathode electrode, but is not limited thereto.

As shown in FIG. 5, the plurality of transistors can comprise a driving transistor DT that supplies current to the light emitting devices LD and a scan transistor ST that supplies a data voltage to the gate electrode of the driving transistor DT. The driving transistor DT can comprise a gate electrode connected to a source electrode of the scan transistor ST, a source electrode connected to a high potential voltage line to which a high potential voltage is applied, and a drain electrode connected to the first electrodes of the light emitting devices LD. The scan transistor ST can comprise a gate electrode connected to the scan line (Sk, k is an integer satisfying 1≤k≤n), a source electrode connected to the gate electrode of the driving transistor DT, and a drain electrode connected to a data line (Dj, j is an integer satisfying 1≤j≤m.

The capacitor Cst is formed between the gate electrode and the source electrode of the driving transistor DT. The storage capacitor Cst charges the difference between the gate voltage and source voltage of the driving transistor DT.

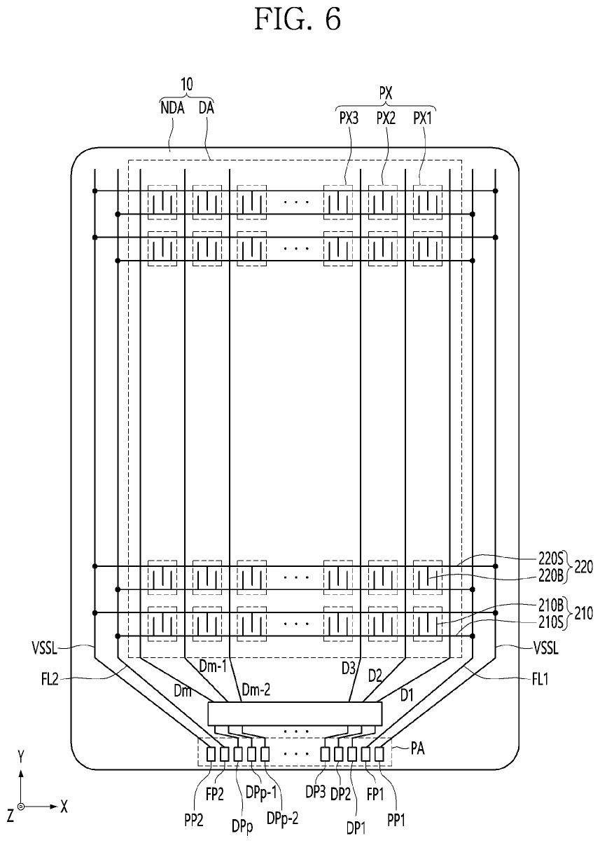

The driving transistor DT and the scan transistor ST can be formed of a thin film transistor. In addition, in FIG. 6, the driving transistor DT and the scan transistor ST are mainly described as being formed of a P-type metal oxide semiconductor field-effect transistor (MOSFET), but is not limited thereto. The driving transistor DT and the scan transistor ST can be formed of an N-type MOSFET. In this instance, the positions of the source and drain electrodes of each of the driving transistor DT and scan transistor ST can be changed.

In addition, in FIG. 5, it is illustrated in which each of the first sub-pixel PX1, the second sub-pixel PX2, and the third sub-pixel PX3 has one driving transistor DT, one scan transistor ST, and one capacitor Cst, but is not limited thereto. Each of the first sub-pixel PX1, the second sub-pixel PX2, and the third sub-pixel PX3 can comprise a plurality of scan transistors ST and a plurality of capacitors Cst.

Since the second sub-pixel PX2 and the third sub-pixel PX3 can be represented by substantially the same circuit diagram as the first sub-pixel PX1, detailed descriptions thereof will be omitted.

The driving circuit 20 outputs signals and voltages for driving the display panel 10. For this purpose, the driving circuit 20 can comprise a data driving device 21 and a timing controller 22.

The data driving device 21 receives digital video data DATA and source control signal DCS from the timing controller 22. The data driving device 21 converts digital video data DATA into analog data voltages according to the source control signal DCS and supplies them to the data lines D1 to Dm of the display panel 10.

The timing controller 22 receives digital video data DATA and timing signals from the host system. The timing signals can comprise a vertical synchronization signal, a horizontal synchronization signal, a data enable signal, and a dot clock. The host system can be an application processor in a smartphone or tablet PC, a monitor, or a system-on-chip in a TV.

The timing controller 22 generates control signals to control the operation timing of the data driving device 21 and the scan driving device 30. The control signals can comprise a source control signal DCS for controlling the operation timing of the data driving device 21 and a scan control signal SCS for controlling the operation timing of the scan driving device 30.

The driving circuit 20 can be disposed in the non-display area NDA provided on one side of the display panel 10. The driving circuit 20 can be formed of an integrated circuit IC and mounted on the display panel 10 using a chip on glass COG method, a chip on plastic COP method, or an ultrasonic bonding method, but is not limited to thereto. For example, the driving circuit 20 can be mounted on a circuit board (not shown) rather than on the display panel 10.

The data driving device 21 can be mounted on the display panel 10 using a COG method, a COP method, or an ultrasonic bonding method, and the timing control unit 22 can be mounted on a circuit board.

The scan driving device 30 receives a scan control signal SCS from the timing controller 22. The scan driving device 30 generates scan signals according to the scan control signal SCS and supplies them to the scan lines S1 to Sn of the display panel 10. The scan driving device 30 can comprise a plurality of transistors and can be formed in the non-display area NDA of the display panel 10. Alternatively, the scan driving device 30 can be formed as an integrated circuit, and in this instance, can be mounted on a gate flexible film attached to the other side of the display panel 10.

The circuit board can be attached to pads provided at one edge of the display panel 10 using an anisotropic conductive film. For this reason, the lead lines of the circuit board can be electrically connected to the pads. The circuit board can be a flexible printed circuit board, a printed circuit board, or a flexible film such as a chip on film. The circuit board can be bent toward the lower side of the display panel 10. For this reason, one side of the circuit board can be attached to one edge of the display panel 10, and the other side can be disposed on the lower side the display panel 10 and can be connected to a system board on which the host system is mounted.

The power supply circuit 50 can generate voltages necessary for driving the display panel 10 from the main power supplied from the system board and supply them to the display panel 10. For example, the power supply circuit 50 can generate a high potential voltage VDD and a low potential voltage VSS for driving the light emitting devices LD of the display panel 10 from the main power supply to supply the high potential voltage VDD and the low potential voltage VSS to high potential voltage line and low potential voltage line. Additionally, the power supply circuit 50 can generate and supply driving voltages for driving the driving circuit 20 and the scan driving device 30 from the main power supply.

FIG. 6 is a plan view showing the display panel of FIG. 4 in detail. In FIG. 6, for convenience of explanation, data pads (DP1 to DPp, p is an integer of 2 or more), the floating pads FP1 and FP2, the power pads PP1 and PP2, the floating lines FL1 and FL2, the low potential voltage line VSSL, the data lines D1 to Dm, the first pad electrodes 210, and the second pad electrodes 220 are shown.

Referring to FIG. 6, the data lines D1 to Dm, the first pad electrodes 210, the second pad electrodes 220, and the pixels PX can be disposed in the display area DA of the display panel 10.

The data lines D1 to Dm can extend long in the second direction (Y-axis direction). One side of each of the data lines D1 to Dm can be connected to the driving circuit (20 in FIG. 4). For this reason, the data voltages of the driving circuit 20 can be applied to the data lines D1 to Dm.

The first pad electrodes 210 can be disposed to be spaced apart at predetermined distance in the first direction (X-axis direction). For this reason, the first pad electrodes 210 may not overlap the data lines D1 to Dm. Among the first pad electrodes 210, the first pad electrodes 210 disposed at the right edge of the display area DA can be connected to the first floating line FL1 in the non-display area NDA. Among the first pad electrodes 210, the first pad electrodes 210 disposed at the left edge of the display area DA can be connected to the second floating line FL2 in the non-display area NDA.

Each of the second pad electrodes 220 can extend long in the first direction (X-axis direction). For this reason, the second pad electrodes 220 can overlap the data lines D1 to Dm. Additionally, the second pad electrodes 220 can be connected to the low potential voltage line VSSL in the non-display area NDA. For this reason, the low potential voltage of the low potential voltage line VSSL can be applied to the second pad electrodes 220.

A pad portion PA, the driving circuit 20, the first floating line FL1, the second floating line FL2, and the low potential voltage line VSSL can be disposed in the non-display area NDA of the display panel 10. The pad portion PA can comprise the data pads DP1 to DPp, the floating pads FP1 and FP2, and the power pads PP1 and PP2.

The pad portion PA can be disposed at one edge of the display panel 10, for example, at the lower edge. The data pads DP1 to DPp, the floating pads FP1 and FP2, and the power pads PP1 and PP2 can be disposed side by side in the first direction (X-axis direction) in the pad portion PA.

A circuit board can be attached to the data pads DP1 to DPp, the floating pads FP1 and FP2, and the power pads PP1 and PP2 using an anisotropic conductive film. For this reason, the circuit board, the data pads DP1 to DPp, the floating pads FP1 and FP2, and the power pads PP1 and PP2 can be electrically connected.

The driving circuit 20 can be connected to the data pads DP1 to DPp through link lines. The driving circuit 20 can receive digital video data DATA and timing signals through the data pads DP1 to DPp. The driving circuit 20 can convert digital video data DATA into analog data voltages and supply them to the data lines D1 to Dm of the display panel 10.

The low potential voltage line VSSL can be connected to the first power pad PP1 and the second power pad PP2 of the pad portion PA. The low potential voltage line VSSL can extend long in the second direction (Y-axis direction) from the non-display area NDA outside the left and right sides of the display area DA. The low potential voltage line VSSL can be connected to the second pad electrode 220. For this reason, the low potential voltage of the power supply circuit 50 can be applied to the second pad electrode 220 through the circuit board, the first power pad PP1, the second power pad PP2, and the low potential voltage line VSSL.

The first floating line FL1 can be connected to the first floating pad FP1 of the pad portion PA. The first floating line FL1 can extend long in the second direction (Y-axis direction) from the non-display area NDA outside the left and right sides of the display area DA. The first floating pad FP1 and the first floating line FL1 can be dummy pads and dummy lines to which no voltage is applied.

The second floating line FL2 can be connected to the second floating pad FP2 of the pad portion PA. The first floating line FL1 can extend long in the second direction (Y-axis direction) from the non-display area NDA outside the left and right sides of the display area DA. The second floating pad FP2 and the second floating line FL2 can be dummy pads and dummy lines to which no voltage is applied.

Meanwhile, since the light emitting devices (LD in FIG. 5) have a very small size, it is very difficult to mount the light emitting elements LD into the first sub-pixel PX1, the second sub-pixel PX2, and the third sub-pixel PX3 of each of the pixels PX.

To solve this problem, an alignment method using dielectrophoresis method was proposed.

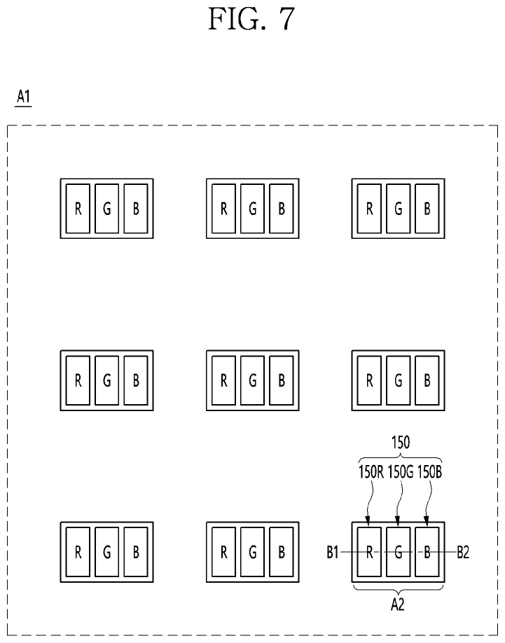

That is, in order to align the light emitting devices (150 in FIG. 6) during the manufacturing process of the display panel 10, an electric field can be formed in the first sub-pixel PX1, the second sub-pixel PX2, and the third sub-pixel PX3 of each of the pixels PX. Specifically, during the manufacturing process, a dielectrophoretic force can be applied to the light emitting devices (150 in FIG. 7) using a dielectrophoresis method, so that that the light emitting elements (150 in FIG. 7) can be aligned in each of the first sub-pixel PX1, the second sub-pixel PX2, and the third sub-pixel PX3.

However, during the manufacturing process, it is difficult to drive the thin film transistors and apply a ground voltage to the first pad electrodes 210.

Therefore, in the completed display device, the first pad electrodes 210 can be disposed to be spaced apart at predetermined distance in the first direction (X-axis direction), but during the manufacturing process, the first pad electrodes 210 may be not disconnected in the first direction (X-axis direction) but can be disposed to extend long.

For this reason, the first pad electrodes 210 can be connected to the first floating line FL1 and the second floating line FL2 during the manufacturing process. Therefore, the first pad electrodes 210 can receive the ground voltage through the first floating line FL1 and the second floating line FL2. Therefore, after aligning the light emitting devices (150 in FIG. 7) using a dielectrophoresis method during the manufacturing process, the first pad electrodes 210 can be disconnected, so that that the first pad electrodes 210 can be disposed to be spaced apart at predetermined distance in the first direction (X-axis direction).

Meanwhile, the first floating line FL1 and the second floating line FL2 can be lines for applying the ground voltage during the manufacturing process, and no voltage can be applied in the completed display device. Alternatively, in the completed display device, the ground voltage can be applied to the first floating line FL1 and the second floating line FL2 to prevent static electricity or to drive the light emitting devices (150 in FIG. 7).

FIG. 7 is an enlarged view of a first panel area in the display device of FIG. 3.

According to FIG. 7, the display device 100 of the embodiment can be manufactured by mechanically and electrically connecting a plurality of panel areas, such as the first panel area A1, by tiling.

The first panel area A1 can comprise a plurality of light emitting devices 150 disposed for each unit pixel (PX in FIG. 4).

For example, the unit pixel PX can comprise a first sub-pixel PX1, a second sub-pixel PX2, and a third sub-pixel PX3. For example, a plurality of red light emitting devices 150R can be disposed in the first sub-pixel PX1, a plurality of green light emitting devices 150G can be disposed in the second sub-pixel PX2, and a plurality of blue light emitting devices 150B can be disposed in the third sub-pixel PX3. The unit pixel PX can further comprise a fourth sub-pixel in which no light emitting device is disposed, but is not limited thereto.

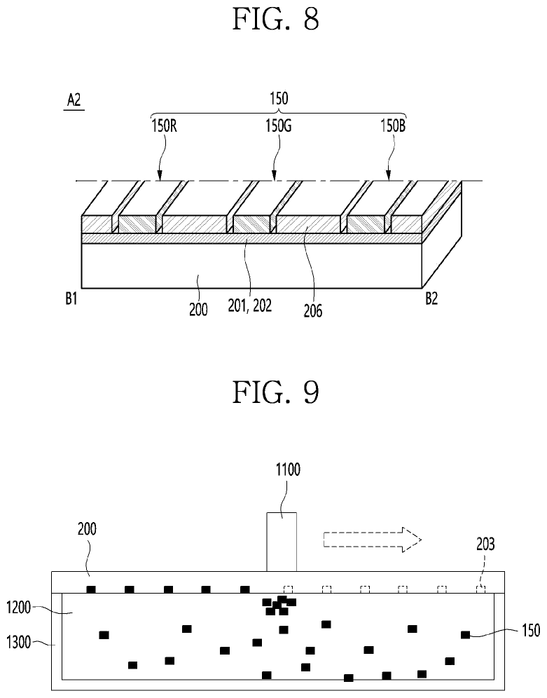

FIG. 8 is an enlarged view of area A2 in FIG. 7.

Referring to FIG. 8, the display device 100 of the embodiment can comprise a substrate 200, assembling wirings 201 and 202, an insulating layer 206, and a plurality of light emitting devices 150. More components can be included than these.

The assembling wiring can comprise a first assembling wiring 201 and a second assembling wiring 202 that are spaced apart from each other. The first assembling wiring 201 and the second assembling wiring 202 can be provided to generate dielectrophoretic force to assemble the light emitting device 150.

The light emitting device 150 can comprise, but is not limited thereto, a red light emitting device 150, a green light emitting device 150G, and a blue light emitting device 150B0 to form an unit sub-pixel, and it is also possible to implement red and green colors by using red phosphors and green phosphors, respectively.

The substrate 200 can be formed of glass or polyimide. Additionally, the substrate 200 can comprise a flexible material such as polyethylene naphthalate (PEN) or polyethylene terephthalate (PET). Additionally, the substrate 200 can be made of a transparent material, but is not limited thereto.

The insulating layer 206 can comprise an insulating and flexible material such as polyimide, PEN, PET, etc., and can be integrated with the substrate 200 to form one substrate.

The insulating layer 206 can be a conductive adhesive layer that has adhesiveness and conductivity, and the conductive adhesive layer can be flexible and enable a flexible function of the display device. For example, the insulating layer 206 can be an anisotropic conductive film (ACF) or a conductive adhesive layer such as an anisotropic conductive medium or a solution comprising conductive particles. The conductive adhesive layer can be a layer that is electrically conductive in a direction perpendicular to the thickness, but electrically insulating in a direction horizontal to the thickness.

The insulating layer 206 can comprise an assembly hole 203 into which the light emitting device 150 is inserted. Therefore, during self-assembly, the light emitting device 150 can be easily inserted into the assembly hole 203 of the insulating layer 206. The assembly hole 203 can be called an insertion hole, a fixing hole, an alignment hole, etc.

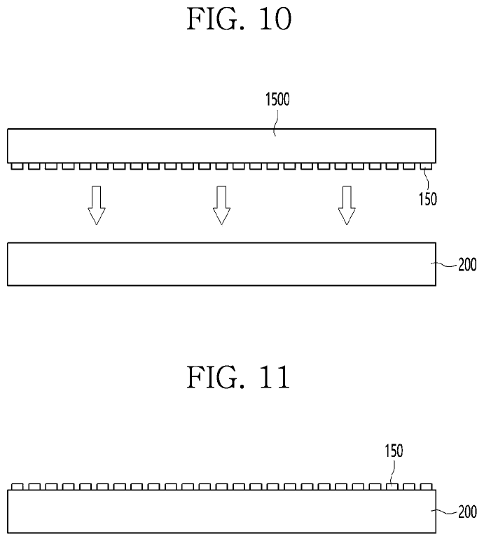

Meanwhile, methods of mounting the light emitting device 150 on the substrate 200 can comprise, for example, a self-assembly method (FIG. 9) and a transfer method (FIGS. 10 and 11).

FIG. 9 is a diagram showing an example in which a light emitting device according to an embodiment is assembled on a substrate by a self-assembly method.

The self-assembly method of the light emitting device will be described with reference to FIGS. 8 and 9.

The substrate 200 can be a panel substrate of a display device. In the following description, the substrate 200 will be described as a panel substrate of a display device, but the embodiment is not limited thereto.

The substrate 200 can be formed of glass or polyimide. Additionally, the substrate 200 can comprise a flexible material such as PEN or PET. Additionally, the substrate 200 can be made of a transparent material, but is not limited thereto.

Referring to FIG. 9, the light emitting device 150 can be inserted into the chamber 1300 filled with the fluid 1200. The fluid 1200 can be water such as ultrapure water, but is not limited thereto. The chamber can be called a water tank, container, vessel, etc.

After this, the substrate 200 can be disposed on the chamber 1300. Depending on the embodiment, the substrate 200 can be input into the chamber 1300.

As shown in FIG. 8, a pair of assembling wirings 201 and 202 corresponding to each of the light emitting devices 150 to be assembled can be disposed on the substrate 200.

The assembling wirings 201 and 202 can be formed of transparent electrodes (ITO) or can comprise a metal material with excellent electrical conductivity. For example, the assembling wirings 201 and 202 can be formed of at least one of titanium (Ti), chromium (Cr), nickel (Ni), aluminum (Al), platinum (Pt), gold (Au), tungsten (W), and molybdenum (Mo) or an alloy thereof.

An electric field can be formed in the assembling wirings 201 and 202 by an externally-supplied voltage, and a dielectrophoretic force can be formed between the assembling wirings 201 and 202 by the electric field. The light emitting device 150 can be fixed to the assembly hole 203 on the substrate 200 by this dielectrophoretic force.

The distance between the assembling wirings 201 and 202 can be formed to be smaller than the width of the light emitting device 150 and the width of the assembly hole 203, so that that the assembly position of the light emitting device 150 using an electric field can be fixed more precisely.

An insulating layer 206 can be formed on the assembling wirings 201 and 202 to protect the assembling wirings 201 and 202 from the fluid 1200 and prevent leakage of current flowing through the assembling wirings 201 and 202. The insulating layer 206 can be formed as a single layer or multilayer of an inorganic insulator such as silica or alumina or an organic insulator.

Additionally, the insulating layer 206 can comprise an insulating and flexible material such as polyimide, PEN, PET, etc., and can be integrated with the substrate 200 to form one substrate.

The insulating layer 206 can be an adhesive insulating layer or a conductive adhesive layer with conductivity. The insulating layer 206 can be flexible and can enable flexible functions of the display device.

The insulating layer 206 has a barrier rib, and the assembly hole 203 can be formed by this barrier rib. For example, when forming the substrate 200, a portion of the insulating layer 206 can be removed, so that that each of the light emitting devices 150 can be assembled into an assembly hole 203 of the insulating layer 206.

The assembly hole 203 in which the light emitting devices 150 are coupled can be formed in the substrate 200, and the surface where the assembly hole 203 is formed can be in contact with the fluid 1200. The assembly hole 203 can guide the exact assembly position of the light emitting device 150.

Meanwhile, the assembly hole 203 can have a shape and size corresponding to the shape of the light emitting device 150 to be assembled at the corresponding position. Accordingly, it is possible to prevent another light emitting device from being assembled in the assembly hole 203 or a plurality of light emitting devices from being assembled in the assembly hole 203.

Referring again to FIG. 9, after the substrate 200 is disposed, the assembly device 1100 comprising a magnetic material can move along the substrate 200. For example, a magnet or electromagnet can be used as a magnetic material. The assembly device 1100 can move while in contact with the substrate 200 in order to maximize the area to which the magnetic field is applied within the fluid 1200. Depending on the embodiment, the assembly device 1100 can comprise a plurality of magnetic materials or a magnetic material of a size corresponding to that of the substrate 200. In this instance, the moving distance of the assembly device 1100 can be limited to within a predetermined range.

The light emitting device 150 in the chamber 1300 can move toward the assembly device 1100 by the magnetic field generated by the assembly device 1100.

While moving toward the assembly device 1100, the light emitting device 150 can enter the assembly hole 203 and come into contact with the substrate 200.

At this time, by the electric field applied by the assembling wiring 201 and 202 formed on the substrate 200, the light emitting element 150 in contact with the substrate 200 can be prevented from being separated by movement of the assembly device 1100.

In other words, the time required for each of the light emitting devices 150 to be assembled on the substrate 200 can be drastically shortened by the self-assembly method using the electromagnetic field described above, so that that large-area and high-pixel display can be implemented more quickly and economically.

A predetermined solder layer 225 can be further formed between the light emitting device 150 and the second pad electrode 222 assembled on the assembly hole 203 of the substrate 200 to improve the bonding force of the light emitting device 150.

Thereafter, the first pad electrode 221 can be connected to the light emitting device 150 and power can be applied to the light emitting device 150.

Next, the molding layer 230 can be formed on the barrier rib 200S and the assembly hole 203 of the substrate 200. The molding layer 230 can be transparent resin or resin comprising a reflective material or a scattering material.

FIGS. 10 and 11 are diagrams showing an example in which a light emitting device according to an embodiment is transferred to a substrate by a transfer method.

As shown in FIG. 10, a plurality of light emitting devices 150 can be attached to the substrate 1500. For example, the substrate 1500 can be a donor substrate that serves as an intermediate medium for mounting the light emitting devices 150 on the display substrate. In this instance, the plurality of light emitting devices 150 manufactured on the wafer can be attached to the substrate 1500, and the plurality of light emitting devices 150 attached on the substrate 1500 can be transferred onto the display substrate.

Hereinafter, the substrate 1500 will be described as a donor substrate, but the substrate 1500 can be a display substrate on which the plurality of light emitting devices 150 are directly transferred without passing through the donor substrate.

As shown in FIG. 10, after the substrate 1500 is positioned on the display substrate 200, an alignment process can be performed so that each of the plurality of light emitting devices 150 on the substrate 1500 can correspond to each pixel of the display substrate 200.

Thereafter, by pressing the substrate 1500 (or the display substrate 200), the plurality of light emitting elements 150 on the substrate 1500 can be transferred to each pixel on the display substrate 200, as shown in FIG. 10.

Afterwards, a plurality of light emitting devices 150 can be attached to the display substrate 200 through a post-process and the plurality of light emitting devices 150 can be electrically connected to a power source, so that that the plurality of light emitting devices 150 can emit light to display an image.

Meanwhile, the display device according to the embodiment can display an image using a light emitting device. The light emitting device of the embodiment is a self-emissive element that emits light by itself by applying electricity, and can be a semiconductor light emitting device. Since the light emitting device of the embodiment is made of an inorganic semiconductor material, it can be resistant to deterioration and can have a semi-permanent lifespan, so that it can provide stable light and can contribute to display devices realizing high-quality and high-definition images.

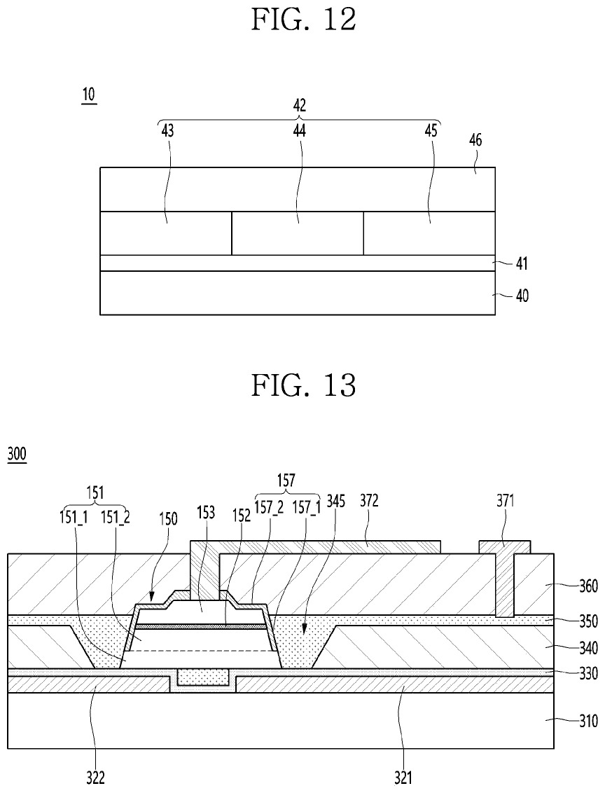

For example, a display device can use a light emitting device as a light source and can have a color generator on the light emitting device, so that images can be displayed using this color generator (FIG. 12).

Although not shown, the display device can display images through a display panel in which a plurality of light emitting devices that generate different color lights are disposed in pixels, respectively.

FIG. 12 is a cross-sectional view schematically showing the display panel of FIG. 4.

Referring to FIG. 12, the display panel 10 of the embodiment can comprise a first substrate 40, a light emitting structure 41, a color generator 42, and a second substrate 46. The display panel 10 of the embodiment can comprise more components than these, but is not limited thereto. The first substrate 40 can be the substrate 200 shown in FIG. 8.

Although not shown, at least one insulating layer can be disposed between the first substrate 40 and the light emitting structure 41, between the light emitting structure 41 and the color generator 42, and/or between the color generator 42 and the second substrate 46, but is not limited thereto.

The first substrate 40 can support the light emitting structure 41, the color generator 42, and the second substrate 46. The first substrate 40 can comprise various components as described above, such as the data lines (D1 to Dm, m is an integer of 2 or more), the scan lines S1 to Sn, the high potential voltage line, the low potential voltage line as shown in FIG. 4, a plurality of transistors ST and DT and at least one capacitor Cst as shown in FIG. 5, the first pad electrode 210 and the second pad 220 as shown in FIG. 6.

The first substrate 40 can be formed of glass or a flexible material, but is not limited thereto.

The light emitting structure 41 can provide light to the color generating unit 42. The light emitting structure 41 can comprise a plurality of light sources that emit light by themselves by applying electricity. For example, the light source can comprise a light emitting device (150 in FIG. 7).

As an example, the plurality of light emitting devices 150 can be disposed separately for each sub-pixel of the pixel and can emit light independently by controlling each sub-pixel.

As another example, the plurality of light emitting devices 150 can be disposed regardless of pixel division and emit light simultaneously from all sub-pixels.

The light emitting device 150 of the embodiment can emit blue light, but is not limited thereto. For example, the light emitting device 150 of the embodiment can emit white light or purple light.

Meanwhile, the light emitting device 150 can emit red light, green light, and blue light for each sub-pixel. For this purpose, for example, a red light emitting device that emits red light can be disposed in the first sub-pixel, that is, the red sub-pixel, a green light emitting device that emits green light can be disposed in the second sub-pixel, that is, the green sub-pixel, a blue light emitting device that emits blue light can be disposed in the third sub-pixel, that is, the blue sub-pixel.

For example, each of the red light emitting device, the green light emitting device, and the blue light emitting device can comprise the group II-VI element or the group III-V compound, but is not limited thereto. For example, the group III-V compound can be selected from the group consisting of: a binary compound selected from the group consisting of GaN, GaP, GaAs, GaSb, AlN, AlP, AlAs, AlSb, InN, InP, InAs, InSb, and the mixture thereof; a ternary compound selected from the group consisting of GaNP, GaNAs, GaNSb, GaPAs, GaPSb, AlInP, AlNP, AlNAs, AlNSb, AlPAs, AlPSb, InNP, InNAs, InNSb, InPAs, InPSb, GaAlNP, and mixtures thereof; and a quaternary compound selected from the group consisting of AlGaInP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and the mixture thereof.

The color generator 42 can generate color light that is different from the light provided from the light emitter 41.

For example, the color generator 42 can comprise a first color generator 43, a second color generator 44, and a third color generator 45. The first color generator 43 can correspond to the first sub-pixel PX1 of the pixel, the second color generator 44 can correspond to the second sub-pixel PX2 of the pixel, and the third color generator 45 can correspond to the third sub-pixel PX3 of the pixel.

The first color generator 43 can generate the first color light based on the light provided from the light emitting structure 41, the second color generator 44 can generate the second color light based on the light provided from the light emitting structure 41, and the third color generator 45 can generate the third color light based on the light provided from the light emitter 41. For example, the first color generator 43 can output the blue light of the light emitter 41 as red light, the second color generator 44 can output the blue light of the light emitter 41 as green light, and the third color generator 45 can output the blue light of the light emitter 41 as it is.

As an example, the first color generator 43 can comprise a first color filter, the second color generator 44 can comprise a second color filter, and the third color generator 45 can comprise a third color filter.

The first color filter, the second color filter, and the third color filter can be formed of a transparent material that allows light to pass through.

For example, at least one of the first color filter, second color filter, and third color filter can comprise quantum dots.

The quantum dots of the example can be selected from group II-VI elements, group III-V compounds, group IV-VI compounds, group IV elements, group VI elements, and combinations thereof.

The group II-VI compound can be selected from the group consisting of a binary compound selected from the group consisting of CdSe, CdTe, ZnS, ZnSe, ZnTe, ZnO, HgS, HgSe, HgTe, MgSe, MgS, and the mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and the mixture thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and the mixture thereof.

For example, the group III-V compound can be selected from the group consisting of: a binary compound selected from the group consisting of GaN, GaP, GaAs, GaSb, AlN, AlP, AlAs, AlSb, InN, InP, InAs, InSb, and the mixture thereof; a ternary compound selected from the group consisting of GaNP, GaNAs, GaNSb, GaPAs, GaPSb, AlInP, AlNP, AlNAs, AlNSb, AlPAs, AlPSb, InNP, InNAs, InNSb, InPAs, InPSb, GaAlNP, and the mixture thereof; and a quaternary compound selected from the group consisting of AlGaInP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and the mixture thereof.

The group IV-VI compound can be selected from the group consisting of: a binary compound selected from the group consisting of SnS, SnSe, SnTe, PbS, PbSe, PbTe, and the mixture thereof; a ternary compound selected from the group consisting of SnSeS, SnSeTe, SnSTe, PbSeS, PbSeTe, PbSTe, SnPbS, SnPbSe, SnPbTe, and the mixture thereof; and a quaternary compound selected from the group consisting of SnPbSSe, SnPbSeTe, SnPbSTe, and the mixture thereof.

The group IV element can be selected from the group consisting of Si, Ge, and mixtures thereof. The group IV element can be a binary compound selected from the group consisting of SiC, SiGe, and mixtures thereof.

These quantum dots can have a full width of half maximum (FWHM) of the emission wavelength spectrum of approximately 45 nm or less, and light emitted through the quantum dots can be emitted in all directions. Accordingly, the viewing angle of the light emitting display device can be improved.

On the other hand, the quantum dots can have the form of nanoparticles, nanotubes, nanowires, nanofibers, nanoplate-shaped particles, etc. having spherical, pyramidal, multi-arm, or cubic shape, but is not limited to thereto.

For example, when the light emitting device 150 emits blue light, the first color filter can comprise red quantum dots, and the second color filter can comprise green quantum dots. The third color filter may not comprise quantum dots, but is not limited thereto. For example, the blue light from the light emitting device 150 can be absorbed by the first color filter, and the absorbed blue light can be wavelength shifted by the red quantum dots to output red light. For example, blue light from the light emitting device 150 can be absorbed by the second color filter, and the absorbed blue light can be wavelength shifted by the green quantum dots to output green light. For example, blue light from the foot and device can be absorbed by the third color filter, and the absorbed blue light can be emitted as it is.

Meanwhile, when the light emitting device 150 emits white light, not only the first color filter and the second color filter but also the third color filter can comprise quantum dots. That is, the white light of the light emitting device 150 can be wavelength shifted to blue light by the quantum dots comprised in the third color filter.

For example, at least one of the first color filter, the second color filter, and the third color filter can comprise a phosphor. For example, some of the first color filters, second color filters, and third color filters can comprise quantum dots, and other color filters can comprise phosphors. For example, each of the first color filter and the second color filter can comprise a phosphor and a quantum dot. For example, at least one of the first color filter, the second color filter, and the third color filter can comprise scattering particles. Since the blue light incident on each of the first color filter, the second color filter, and the third color filter is scattered by the scattering particles and the scattered blue light is color shifted by the corresponding quantum dot, light output efficiency can be improved.

As another example, the first color generator 43 can comprise a first color conversion layer and a first color filter. The second color generator 44 can comprise a second color converter and a second color filter. The third color generator 45 can comprise a third color conversion layer and a third color filter. Each of the first color conversion layer, the second color conversion layer, and the third color conversion layer can be disposed adjacent to the light emitting structure 41. The first color filter, second color filter, and third color filter can be disposed adjacent to the second substrate 46.

For example, the first color filter can be disposed between the first color conversion layer and the second substrate 46. For example, the second color filter can be disposed between the second color conversion layer and the second substrate 46. For example, the third color filter can be disposed between the third color conversion layer and the second substrate 46.

For example, the first color filter can be in contact with the upper surface of the first color conversion layer and have the same size as the first color conversion layer, but is not limited thereto. For example, the second color filter can be in contact with the upper surface of the second color conversion layer and can have the same size as the second color conversion layer, but is not limited thereto. For example, the third color filter can be in contact with the upper surface of the third color conversion layer and can have the same size as the third color conversion layer, but is not limited thereto.

For example, the first color conversion layer can comprise red quantum dots, and the second color conversion layer can comprise green quantum dots. The third color conversion layer may not comprise quantum dots. For example, the first color filter can comprise a red-based material that selectively transmits red light converted in the first color conversion layer, the second color filter can comprise a green material that selectively transmits green light converted in the second color conversion layer, and the third color filter can comprise a blue-based material that selectively transmits blue light transmitted as it is through the third color conversion layer.

Meanwhile, when the light emitting device 150 emits white light, not only the first color conversion layer and the second color conversion layer but also the third color conversion layer can comprise quantum dots. That is, the white light of the light emitting device 150 can be wavelength shifted to blue light by the quantum dots comprised in the third color filter.

Referring again to FIG. 12, the second substrate 46 can be disposed on the color generator 42 to protect the color generator 42. The second substrate 46 can be formed of glass, but is not limited thereto.

The second substrate 46 can be called a cover window, cover glass, etc.

The second substrate 46 can be formed of glass or a flexible material, but is not limited thereto.

Meanwhile, in the embodiment, the display panel can be manufactured using a self-assembly method. In an embodiment, after a semiconductor light emitting device is assembled in an assembly hole through self-assembly, a conductive liquid photosensitive film can be applied in the assembly hole, and then ultraviolet light can be irradiated to cure the conductive liquid photosensitive film such that a first connection part can be formed. At this time, a protective layer 157 can be formed on the remaining area except for a portion of the side surface of the semiconductor light emitting device. A portion of the side surface of the semiconductor light emitting device assembled in the assembly hole can be electrically connected to the first connection part. That is, a portion of the side surface of the semiconductor light emitting device along a perimeter of a side surface of the semiconductor light emitting device can be in contact with the first connection part.

Accordingly, high luminance can be implemented by maximizing the contact area between the first connection part and the semiconductor light emitting device. In the embodiment, the first connection part can be disposed within the assembly hole, so that that even if the semiconductor light emitting device is biased to one side within the assembly hole, the semiconductor light emitting device can be always electrically connected to the first connection part, thereby fundamentally blocking lighting defects. In the embodiment, since the contact area between the first connection part and the semiconductor light emitting device within the assembly hole of each pixel is constant, there is no luminance difference between each pixel, thereby improving image quality.

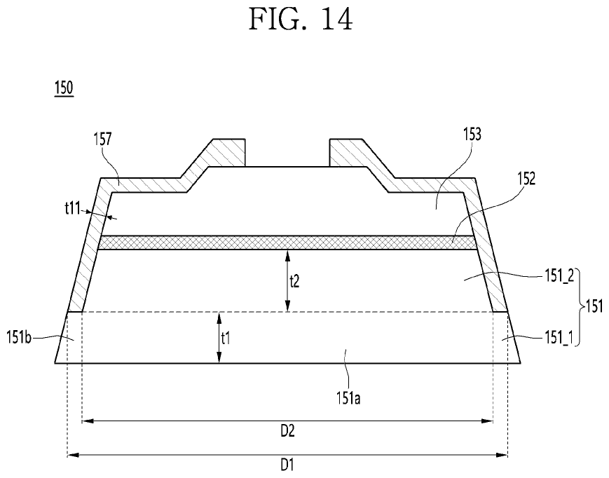

Display devices according to various embodiments having various technical advantages will be described in detail with reference to FIGS. 13 to 28.

FIG. 13 is a cross-sectional view showing a display device according to a first embodiment.

Referring to FIG. 13, the display device 300 according to the first embodiment can comprise a substrate 310, a barrier rib 340, a semiconductor light emitting device 150, and a first connection part 350.

Since each of the substrate 310 and the barrier rib 340 is the same as the substrate 200 and the insulating layer 206 shown in FIG. 8, detailed descriptions are omitted.

The barrier rib 340 can be disposed on the substrate 310. The barrier rib 340 can be referred to as an insulating layer. The barrier rib 340 can have a plurality of assembly holes 345. The assembly hole 345 can be provided in a sub-pixel of a pixel, but is not limited thereto. The assembly hole 345 can guide and fix the assembly of the semiconductor light emitting device 150. During self-assembly, the semiconductor light emitting device 150, which is moved by a magnetic body, can move from near the assembly hole 345 into the assembly hole 345 and can be fixed to the assembly hole 345.

Although the assembly hole 345 is shown in the drawing as having an inclined inner side surface, it can also have an inner side surface perpendicular to an upper surface of the substrate 310. The semiconductor foot and the device can be easily inserted into the assembly hole 345 by the assembly hole 345 having an inclined inner side surface.

A semiconductor light emitting device 150 can be disposed in each of the plurality of assembly holes 345 provided on the substrate 310.

The semiconductor light emitting device 150 can be formed of a semiconductor material, for example, a group IV compound or a group III-V compound. The semiconductor light emitting device 150 is a member that generates light according to electrical signal.

As an example, the semiconductor light emitting device 150 disposed in each assembly hole 345 can generate single color light. For example, the semiconductor light emitting device 150 can generate ultraviolet light, purple light, blue light, etc. In this instance, the semiconductor light emitting device 150 disposed in each assembly hole 345 serves as a light source, and images can be displayed by generating light of various colors using this light source. A color conversion layer and a color filter can be provided to generate light of various colors.

As another example, the semiconductor light emitting device 150 disposed in each assembly hole 345 can be one of a blue semiconductor light emitting device, a green semiconductor light emitting device, and a red semiconductor light emitting device. For example, when three assembly holes 345 are disposed in parallel, the semiconductor light emitting device 150 disposed in the first assembly hole 345 can be a blue semiconductor light emitting device, the semiconductor light emitting device 150 disposed in the second assembly hole 345 can be a green semiconductor light emitting device, and the semiconductor light emitting device 150 disposed in the third assembly hole 345 can be a red semiconductor light emitting device.

The first connection part 350 can be a connection member for electrically connecting the first wiring electrode 371 to the semiconductor light emitting device 150. The first connection part 350 can comprise a conductive liquid photosensitive material. The conductive liquid photosensitive material has excellent electrical conductivity and can be a material that can be cured by ultraviolet light. For example, the conductive liquid photosensitive material can be made of SU-8 photopolymer, insulating negative-tone epoxy, etc., but is not limited thereto. Protonically doped polyaniline (PAN) nanoparticles can be added to conductive liquid photosensitive materials to enhance their electrical properties.

For example, after the conductive liquid photosensitive film is formed in the assembly hole 345 and on the barrier rib 340, the photosensitive film can be cured by irradiating ultraviolet light on the conductive liquid photosensitive film to form the first connection part 350.

It can take too long to form a metal film of a certain thickness through the deposition process. Therefore, according to the first embodiment, since the conductive liquid photosensitive film is in a liquid form, a desired thickness can be easily formed. Since it can be easily cured by ultraviolet light, there is an advantage that it can be easily formed to a desired thickness in a desired location of the first connection part 350. In particular, additional materials to enhance conductivity can be added to the conductive liquid photosensitive film, so that that electrical conductivity equivalent to that of metal can be obtained.

Using a conductive liquid photosensitive film, the first connection part 350 having a relatively thick first layer within the assembly hole 345 and a relatively thin second layer on the barrier rib 340 can be easily formed.

In particular, since the conductive liquid photosensitive film is filled in the assembly hole 345 and then hardened to form the first connection part 350, the first connection part 350 can perfectly contact all areas to be electrically connected. For example, the area to be electrically connected can be the entire area around the side surface of the first-first conductivity type semiconductor layer 151_1 of the semiconductor light emitting device 150. Meanwhile, even if the semiconductor light emitting device 150 is located in the assembly hole 345 due to the dielectrophoretic force formed between the first and second assembling wirings 321 and 322, there is a minute space between the semiconductor light emitting device 150 and the first insulating layer 330, and the conductive liquid photosensitive film permeates and fills this space. Accordingly, the first connection part 350 formed on the side surface of the semiconductor light emitting device 150 and the first connection part 350 formed under the lower surface of the semiconductor light emitting device 150 can be formed integrally. Accordingly, the voltage of the first wiring electrode 371 can be applied to not only the side surface but also a lower surface of the semiconductor light emitting device 150 through the first connection part 350. That is, since the area to which the voltage of the first wiring electrode 371 is applied in the semiconductor light emitting device 150 is maximized, the smooth supply of voltage can improve the light output of the semiconductor light emitting device 150, which can lead to an improvement in luminance.

In the embodiment, the first connection part 350 can be electrically connected not only to the lower surface but also to the side surface of the semiconductor light emitting device 150, so that that maximum luminance can be obtained. In addition, since the semiconductor light emitting device 150 of each pixel is stably electrically connected to the first connection part 350, lighting defects can be prevented.

In the embodiment, the area where the first connection part 350 contacts the semiconductor light emitting device 150 can be the same for each pixel, so that the luminance of each pixel is uniform. Therefore, image quality can be improved because there is no luminance difference between pixels.

Meanwhile, in order to connect to the first connection part 350, a portion of the side surface of the semiconductor light emitting device 150 can be formed to be exposed to the outside.

Below, with reference to FIG. 14, the semiconductor light emitting device 150 of the embodiment will be described in detail.

FIG. 14 is a cross-sectional view showing the semiconductor light emitting device of FIG. 13.

The semiconductor light emitting device 150 of the embodiment can comprise a first conductivity type semiconductor layer 151, an active layer 152, a second conductivity type semiconductor layer 153, and a protective layer 157. The protective layer 157 can be called an insulating layer, a passivation layer, etc. The first conductivity type semiconductor layer 151, the active layer 152, and the second conductivity type semiconductor layer 153 can be called light emitting parts.

The first conductivity type semiconductor layer 151, the active layer 152, and the second conductivity type semiconductor layer 153 can be sequentially grown on a wafer (411 in FIG. 16) using deposition equipment such as MOCVD. Thereafter, the second conductivity type semiconductor layer 153, the active layer 152, and the first conductivity type semiconductor layer 151 can be etched along the vertical direction in that order using an etching process. Thereafter, the protective layer 157 can be formed along the remaining area excluding a portion of the side surface of the first conductivity type semiconductor layer 151, that is, perimeters of the other portion of the side surface of the first conductivity type semiconductor layer 151, the side surface of the active layer 152, and the side surface of the second conductivity type semiconductor layer 153, so that the semiconductor light emitting device 150 can be manufactured.

The first conductivity type semiconductor layer 151 can comprise a first conductivity type dopant, and the second conductivity type semiconductor layer 153 can comprise a second conductivity type dopant. For example, the first conductivity type dopant can be an n-type dopant such as silicon (Si), and the second conductivity type dopant can be a p-type dopant such as boron (B).

For example, the first conductivity type semiconductor layer 151 can be a place to generate electrons, and the second conductivity type semiconductor layer 153 can be a place to form holes. The active layer 152 is a place that generates light and can be called a light emitting layer.

The first conductivity type semiconductor layer 151 can comprise a first-first conductivity type semiconductor layer 151_1 and a first-second conductivity type semiconductor layer 151_2. For example, the first-second conductivity type semiconductor layer 151_2 can be disposed on the first-first conductivity type semiconductor layer 151_1.

In the drawing, a boundary between the first-first conductivity type semiconductor layer 151_1 and the first-second conductivity type semiconductor layer 151_2 is divided by a dotted line, but the first-first conductivity type semiconductor layer 151_1 and the first-second conductivity type semiconductor layer 151_2 can be formed integrally with the same material, but is not limited thereto. For example, the first-first conductivity type semiconductor layer 151_1 and the first-second conductivity type semiconductor layer 151_2 can comprise the same dopant, but can comprise different semiconductor materials. For example, the first-first conductivity type semiconductor layer 151_1 and the first-second conductivity type semiconductor layer 151_2 can comprise the same dopant, but can comprise different semiconductor materials. For example, the first-first conductivity type semiconductor layer 151_1 and the first-second conductivity type semiconductor layer 151_2 can comprise the same dopant, but can have different doping concentrations. For example, the doping concentration of the first-first conductivity type semiconductor layer 151_1 can be greater than the doping concentration of the first-second conductivity type semiconductor layer 151_2, but is not limited thereto. For example, the first-first conductivity type semiconductor layer 151_1 can be composed of at least one or more layers.

For example, the first thickness t1 of the first-first conductivity type semiconductor layer 151_1 can be smaller than the second thickness t2 of the first-second conductivity type semiconductor layer 151_2. For example, the first-second conductivity type semiconductor layer 151_2 is a place for generating electrons, and any thickness sufficient to generate electrons is sufficient. Therefore, when the thickness of the first conductivity type semiconductor layer 151 is given, the second thickness t2 of the first-second conductivity type semiconductor layer 151_2 can be determined to be sufficient to generate electrons, and the remaining thickness can be determined by the first thickness t1 of the first-first conductivity type semiconductor layer 151_1. For example, when the thickness of the first conductivity type semiconductor layer 151 is 3 μm and the second thickness t2 of the first conductivity type semiconductor layer 151_2 is 1 μm to sufficiently generate electrons, the first thickness t1 of the first-first conductivity type semiconductor layer 151_1 can be 2 μm. For example, when the thickness of the first conductivity type semiconductor layer 151 is 3 μm and the second thickness t2 of the first-second conductivity type semiconductor layer 151_2 is 2 μm to sufficiently generate electrons, the first thickness t1 of the first-first conductivity type semiconductor layer 151_1 can be 1 μm. The above values are written for convenience of explanation and may differ from the actual product in the example.

For example, the area around the side surface of the first-first conductivity type semiconductor layer 151_1 can be greater than the area of the lower surface of the first-first conductivity type semiconductor layer 151_1. By maximizing the area around the side surface of the first-first conductivity type semiconductor layer 151_1, which is easy to connect the first connecting portion 350, luminance can be improved by maximizing the contact area between the first connection part 350 and the first-first conductivity type semiconductor layer 151_1.

For example, a first diameter D1 of the first-first conductivity type semiconductor layer 151_1 can be greater than a second diameter D2 of the first-second conductivity type semiconductor layer 151_2. In this instance, an outer side surface of the first-first conductivity type semiconductor layer 151_1 and an outer side surface of the protective layer 157 can coincide with a straight line. In the drawing, the first diameter D1 of the first-first conductivity type semiconductor layer 151_1 can be the diameter of an upper surface of the first-first conductivity type semiconductor layer 151_1, and the second diameter D2 of the first-second conductivity type semiconductor layer 151_2 can be the diameter of the lower surface of the first-second conductivity type semiconductor layer 151_2. In contrast, the first diameter D1 of the first-first conductivity type semiconductor layer 151_1 can be the diameter of the lower surface of the first-first conductivity type semiconductor layer 151_1, and the second diameter D2 of the first-second conductivity type semiconductor layer 151_2 can be the diameter of an upper surface of the first-second conductivity type semiconductor layer 151_2.

Meanwhile, the first-first conductivity type semiconductor layer 151_1 can comprise a first region 151a and a second region 151b. The first region 151a can correspond to a center area of the first-first conductivity type semiconductor layer 151_1. The second region 151b can surround the first region 151a. That is, the second region 151b can be located along the perimeter of the first region 151a.

The first region 151a can vertically overlap the first-second conductivity type semiconductor layer 151_2, and the second region 151b can vertically overlap the protective layer 157. For example, the first region 151a can have an area equal to that of the first-second conductivity type semiconductor layer 151_2. The second region 151b can be vertically overlap the protective layer 157 disposed along a perimeter of a side surface of the light emitting part 151 to 153.

When the semiconductor light emitting device 150 of the embodiment is formed by mesa etching, the diameter can gradually increase from an upper side to a lower side of the semiconductor light emitting device 150. Accordingly, the diameter of the active layer 152 can be greater than the diameter of the second conductivity type semiconductor layer 153. The diameter D2 of the first-second conductivity type semiconductor layer 151_2 can be greater than the diameter of the active layer 152. The diameter D1 of the first-first conductivity type semiconductor layer 151_1 can be greater than the diameter D2 of the first-second conductivity type semiconductor layer 151_2. The diameter D1 of the first-first conductive type semiconductor layer 151_1 can be the sum of twice the diameter D2 of the first-second conductivity type semiconductor layer 151_2 and the thickness t11 of the protective layer 157.

Referring again to FIG. 12, the protective layer 157 can protect a light emitting part 151 to 153. The protective layer 157 can prevent the semiconductor light emitting device 150 from turning over during self-assembly, and be formed so that the lower side of the semiconductor light emitting device 150, that is, the lower surface of the first conductive semiconductor layer 151, faces the upper surface of the first insulating layer 330. That is, during self-assembly, the protective layer 157 of the semiconductor light emitting device 150 can be positioned away from the first assembling wiring 321 and the second assembling wiring 322. Since the protective layer 157 is not disposed on the lower side of the semiconductor light emitting device 150, the lower side of the semiconductor light emitting device 150 can be positioned to be close to the first assembling wiring 321 and the second assembling wiring 322.

Therefore, during self-assembly, the lower side of the semiconductor light-emitting device 150 is positioned facing the first insulating layer 330 and the upper side of the semiconductor light-emitting device 150 is positioned toward an upper direction, so that misalignment in which the semiconductor light emitting device 150 is assembled upside down can be prevented.

The protective layer 157 can comprise a first protective layer 157_1 and a second protective layer 157_2.

The first protective layer 157_1 can be a member in contact with the first connection part 350, and the second protective layer 157_2 can be a member in contact with the second insulating layer 360. The first protective layer 157_1 and the second protective layer 157_2 can be formed integrally or can be formed separately from each other.

The first connection part 350 can be disposed not only within the assembly hole 345 but also on the barrier rib 340. When the first connection part 350 is disposed only within the assembly hole 345, it is difficult for the first wiring electrode 371 to be electrically connected to the first connection part 350 disposed in the assembly hole 345 due to process margin or layout design. According to the first embodiment, since the first connection part 350 is disposed on the barrier rib 340, the first wiring electrode 371 can be easily electrically connected to the first connection part 350 through the second insulating layer 360.

For example, the upper surface of the first connection part 350 in the assembly hole 345 and the upper surface of the first connection part 350 on the barrier rib 340 can coincide with a horizontal line, but is not limited thereto.

For example, the upper side of the semiconductor light emitting device 150 can protrude upward from the upper surface of the first connection part 350. The second wiring electrode 372 can be electrically connected to the upper side of the semiconductor light emitting device 150, that is, the second conductivity type semiconductor layer 153, through the barrier rib 340. Accordingly, when the upper surface of the first connection part 350 is disposed close to the upper side of the semiconductor light emitting device 150, an electrical short can occur between the first connection part 350 and the second wiring electrode 372. Therefore, according to the first embodiment, the upper side of the semiconductor light emitting device 150 can protrude upward from the upper surface of the first connection part 350, so that that an electrical short circuit between the first connection part 350 and the second wiring electrode 372 can be prevented by ensuring that the upper surface of the first connection part 350 is spaced apart from the upper side of the semiconductor light emitting device 150.

Meanwhile, the display device 300 according to the first embodiment can comprise a first insulating layer 330, a first assembling wiring 321, a second assembling wiring 322, a second insulating layer 360, a first wiring electrode 371 and a second wiring electrode 372. The display device 300 according to the first embodiment can comprise more components than these.

Since each of the first and second assembling wirings 321 and 322 is the same as the wiring electrodes 201 and 202 shown in FIG. 8, detailed descriptions are omitted.

The first insulating layer 330 can be disposed on the substrate 310. The first and second assembling wirings 321 and 322 can be disposed between the first insulating layer 330 and the substrate 310. The first assembling wiring 321 and the second assembling wiring 322 can be disposed in the same layer, for example, the substrate 310. That is, the first assembling wiring 321 and the second assembling wiring 322 can be in contact with the upper surface of the substrate 310. The first assembling wiring 321 and the second assembling wiring 322 can be spaced apart from each other to prevent electrical short circuit. An alternating voltage can be applied to the first assembling wiring 321 and the second assembling wiring 322, so that that a dielectrophoretic force can be formed between the first assembling wiring 321 and the second assembling wiring 322. The semiconductor light emitting device 150 located in the assembly hole 345 can be fixed by this dielectrophoretic force. Since the first assembling wiring 321 and the second assembling wiring 322 are disposed horizontally side by side on the same layer, the dielectrophoretic force formed between the first assembling wiring 321 and the second assembling wiring 322 can be uniform, so that the semiconductor light emitting device 150 can be correctly positioned at the center of the assembly hole 345.

The first insulating layer 330 can protect the first assembling wiring 321 and the second assembling wiring 322 from fluid (1200 in FIG. 9), and prevent leakage current flowing through the first assembling wiring 321 and the second assembling wiring 322.

The first insulating layer 330 can increase dielectrophoretic force. For example, the first insulating layer 330 can be a dielectric layer. The first insulating layer 330 can be formed of a material with a high dielectric constant. The dielectrophoretic force can be proportional to the dielectric constant of the first insulating layer 330. Accordingly, the dielectrophoretic force formed between the first assembling wiring 321 and the second assembling wiring 322 can be increased by the first insulating layer 330 made of a material with a high dielectric constant, and due to this increased dielectrophoretic force, the semiconductor light emitting device 150 located in the assembly hole 345 can be fixed more firmly.

For example, the first insulating layer 330 can be formed as a single layer or multilayer of an inorganic material such as silica or alumina or an organic material.

For example, the first insulating layer 330 can comprise an insulating and flexible material such as polyimide, PEN, PET, etc. For example, the first insulating layer 330 can be integrated with the substrate 310 to form one substrate. That is, the first assembling wiring 321 and the second assembling wiring 322 can be embedded in the substrate 310.

The first insulating layer 330 can be an adhesive insulating layer or a conductive adhesive layer with conductivity. When the first insulating layer 330 is a conductive adhesive layer, the first assembling wiring 321 and the second assembling wiring 322 can be surrounded by an insulating layer to prevent electrical short circuit between each of the first assembling wiring 321 and the second assembling wiring 322 and the conductive adhesive layer. For example, the first insulating layer 330 can have flexibility and can enable a flexible function of the display device 300.

The second insulating layer 360 can be disposed on the first connection part 350. The second insulating layer 360 can be disposed on the semiconductor light emitting device 150.

The second insulating layer 360 can protect the first connection part 350 and/or the semiconductor light emitting device 150. That is, the second insulating layer 360 can protect the semiconductor light emitting device 150 from external moisture or foreign substances. The second insulating layer 360 can protect the first connection part 350 from moisture or conductive foreign substances.

The second insulating layer 360 can be a planarization film. That is, the upper surface of the second insulating layer 360 has a horizontally flat surface, and the layers disposed on the upper surface of the second insulating layer 360, such as the first wiring electrode 371 and the second wiring electrode 372 or another insulating layer can be easily formed.

The second insulating layer 360 can be formed of an organic material or an inorganic material. The second insulating layer 360 can be formed of a resin material such as epoxy or silicone. The second insulation can be made of a material with excellent light transparency so that light from the semiconductor light emitting device 150 can pass through well.

The second insulating layer 360 can comprise scattering particles so that light from the semiconductor light emitting device 150 can be well scattered. For example, the scattering particles can be included in the second insulating layer 360 corresponding to the semiconductor light emitting device 150 in each pixel, but is not limited thereto.

The first wiring electrode 371 and the second wiring electrode 372 can be electrically connected to the semiconductor light emitting device 150. Although not shown, the second insulating layer 360 can have a first contact hole and a second contact hole. After the second insulating layer 360 is formed on the first connection part 350 and the semiconductor light emitting device 150, the first contact hole and the second contact hole can be formed by etching to penetrate the second insulating layer 360. For example, the first contact hole can be formed in the second insulating layer 360 corresponding to a predetermined area of the first connection part 350. The first contact hole can be formed outside the assembly hole 345, that is, on the barrier rib 340. The first contact hole can be formed in the second insulating layer 360 corresponding to the semiconductor light emitting device 150.

For example, the first wiring electrode 371 can be electrically connected to the first connection part 350 through the first contact hole. Accordingly, the negative voltage supplied to the first wiring electrode 371 can be applied to the first conductivity type semiconductor layer 151 of the semiconductor light emitting device 150 through the first connection part 350.

For example, the second wiring electrode 372 can be electrically connected to the second conductivity type semiconductor layer 153 of the semiconductor light emitting device 150 through the second contact hole. Accordingly, the positive (+) voltage supplied to the second wiring electrode 372 can be applied to the second conductivity type semiconductor layer 153 of the semiconductor light emitting device 150.

Light with luminance corresponding to the current flowing by a negative (−) voltage applied to the first conductivity type semiconductor layer 151 of the semiconductor light emitting device 150 and a positive (+) voltage applied to the second conductivity type semiconductor layer 153 of the semiconductor light emitting device 150 can be generated from the semiconductor light emitting device 150. Therefore, by adjusting the intensity of the current flowing through the semiconductor light emitting device 150, the contrast ratio can be controlled by controlling the luminance of each pixel. At this time, the color light of the semiconductor light emitting device 150 can be determined by the wavelength corresponding to the energy band gap of the active layer 152 of the semiconductor light emitting device 150. That is, if the active layer 152 is made of a material with a large energy band gap, short-wavelength light can be generated, and if the active layer 152 is made of a material with a small energy band gap, long-wavelength light can be generated. Therefore, full color can be implemented by the blue semiconductor light emitting device, green semiconductor light emitting device, and red semiconductor light emitting device in each pixel, and luminance is controlled by adjusting the current intensity of each of the blue semiconductor light emitting device, green semiconductor light emitting device, and red semiconductor light emitting device.

According to the first embodiment, by ensuring that the first wiring electrode 371 and the second wiring electrode 372 can be disposed on the same layer, and the dielectrophoretic force formed between the first wiring electrode 371 and the second wiring electrode 372 can be uniform, the semiconductor light emitting device 150 can be correctly positioned at the center of the assembly hole 345. Accordingly, defects such as defects due to the semiconductor light emitting device 150 being biased to one side within the assembly hole 345, lighting defects, luminance deviation between pixels, and luminance decrease can be prevented.

In particular, the first connection part 350 can be in contact with the entire area of the side surface of the first-first conductivity type semiconductor layer 151_1 along a perimeter of a portion of the first conductivity type semiconductor layer 151 of the semiconductor light emitting device 150, that is, the side surface of the first-first conductivity type semiconductor layer 151_1. Due to this unique arrangement structure, defects such as lighting defects, luminance deviation between pixels, and luminance decrease can be completely blocked.

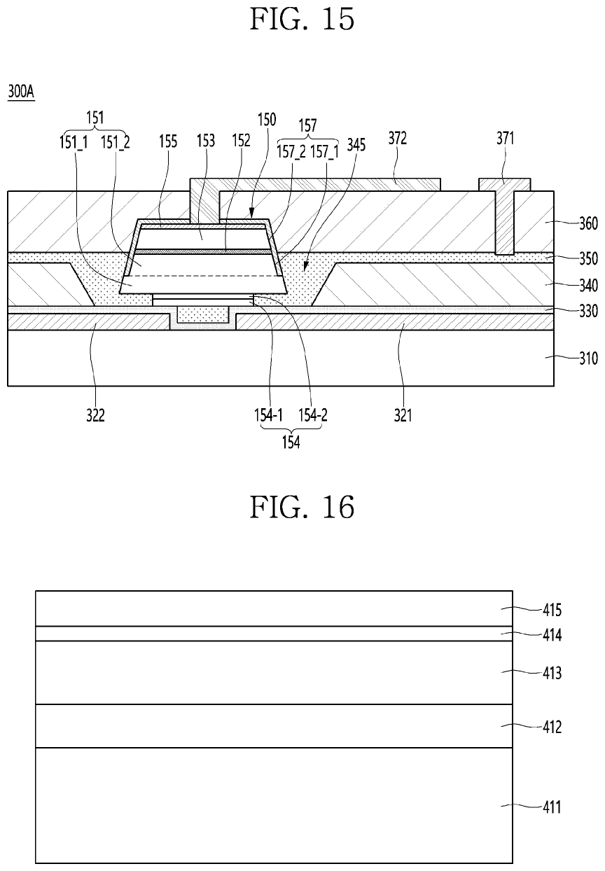

FIG. 15 is a cross-sectional view showing a display device according to a second embodiment.

The second embodiment is the same as the first embodiment except that the first electrode 154 and the second electrode 155 are disposed above and below the light emitting part 151 to 153. Accordingly, in the second embodiment, components having the same shape, structure, and/or function as those of the first embodiment are given the same reference numerals, and detailed descriptions are omitted.

Referring to FIG. 15, the display device 300A according to the second embodiment can comprise a substrate 310, a barrier rib 340, a semiconductor light emitting device 150, and a first connection part 350.

In addition, the display device 300A according to the second embodiment can comprise a first insulating layer 330, a first assembling wiring 321, a second assembling wiring 322, a second insulating layer 360, a first wiring electrode 371 and a second wiring electrode 372. The display device 300A according to the second embodiment can comprise more components than these.

In FIG. 15, the remaining components except for the semiconductor light emitting device 150 have been described in detail in the first embodiment, and detailed descriptions will be omitted.

The semiconductor light emitting device 150 can comprise a light emitting part 151 to 153, a first electrode 154, and a second electrode 155.

The light emitting part can comprise a first conductivity type semiconductor layer 151, an active layer 152, and a second conductivity type semiconductor layer 153. The light emitting part 151 to 153 can comprise more components than these. The first conductivity type semiconductor layer 151 can comprise a first-first conductivity type semiconductor layer 151_1 and a first-second conductivity type semiconductor layer 151_2.

The first electrode 154 can be disposed below the light emitting part 151 to 153. That is, the first electrode 154 can be disposed under the first conductivity type semiconductor layer 151. For example, the first electrode 154 can be disposed on a lower surface of the first-first conductivity type semiconductor layer 151_1.

The first electrode 154 can comprise at least one layer. For example, the first electrode 154 can comprise a bonding layer 154_1 and a magnetic layer 154_2.

When the magnetic layer 154_2 is self-assembled, the semiconductor light emitting device 150 can be magnetized by a magnetic body, so that that the semiconductor light emitting device 150 can be easily moved along the movement of the magnetic body. If the semiconductor light emitting device 150 itself is easily moved along the movement of the magnetic body, the magnetic layer 154_2 can be omitted.

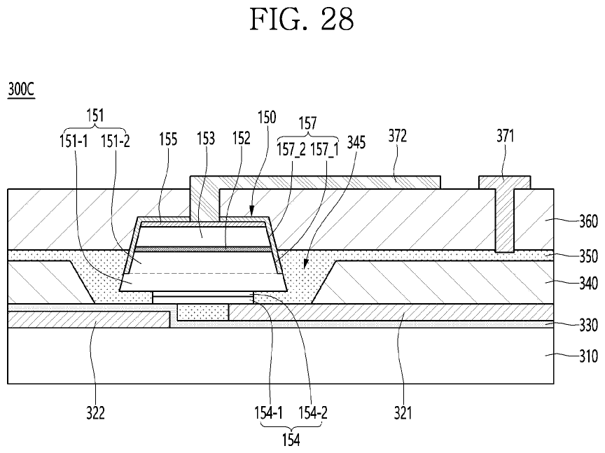

The bonding layer 154_1 can easily attach the semiconductor light emitting device 150 to the first connection part 350. According to the second embodiment, the first connection part 350 can be made of a conductive liquid photosensitive material, so that there can be no problem in bonding to the semiconductor light emitting device 150. In this instance, the bonding layer 154_1 can be omitted. As will be explained later, when the first assembling wiring (321 in FIG. 28) is used as a wiring electrode and the semiconductor light emitting device 150 is electrically connected to the first assembling wiring 321, the semiconductor light emitting device 150 can be easily attached to the first assembling wiring 321 by using the bonding layer 154_1 of the semiconductor light emitting device 150.

For example, the bonding layer 154_1 can comprise tin (Sn), indium (In), etc., and the magnetic layer 154_2 can comprise nickel (Ni), cobalt (Co), iron (Fe), etc. For example, the magnetic layer 154_2 can be disposed on the lower surface of the first-first conductivity type semiconductor layer 151_1, and the bonding layer 154_1 can be disposed on the lower surface of the magnetic layer 154_2.

Although not shown, a layer with excellent electrical conductivity can be added to the first electrode 154.

The second electrode 155 can be disposed on the light emitting part 151 to 153. That is, the second electrode 155 can be disposed on the second conductivity type semiconductor layer 153.

The second electrode 155 can be made of a transparent conductive material, such as ITO. The second electrode 155 can achieve a current spreading effect that allows the current due to the positive voltage supplied from the second wiring electrode 372 to spread evenly throughout the entire area of the first conductivity type semiconductor layer 151. That is, the current can be spread evenly across the entire area of the first conductivity type semiconductor layer 151 by the second electrode 155, and holes can be generated in the entire area of the first conductivity type semiconductor layer 151, so that as the amount of hole generation increases, the amount of light generated by the combination of holes and electrons in the active layer 152 increases, thereby increasing the light output. An increase in light output can lead to an increase in luminance.

Although not shown, the magnetic layer 154_2 can be included in the first electrode 154 rather than the second electrode 155. That is, the magnetic layer 154_2 can be disposed between the layer made of ITO and the second conductivity type semiconductor layer 153, but is not limited thereto. At this time, the magnetic layer 154_2 can be formed to have a very thin thickness on the order of nanometers (nm) in consideration of light transmittance.

According to the second embodiment, the magnetic layer 154_2 can be disposed below the light emitting portions 151 to 153 so that the semiconductor light emitting device 150 can move faster and more quickly according to the movement of the magnetic body during magnetic assembly. Thus, process time can be shortened and assembly yield can be improved.

According to the second embodiment, the second electrode 155, which is a transparent conductive layer, can be disposed on the light emitting part 151 to 153, so that that luminance can be improved by increasing light output due to the current spreading effect.

FIGS. 16 to 26 are diagrams explaining the manufacturing method of the semiconductor light emitting device of FIG. 15.

As shown in FIG. 16, an undoped film 412, a first semiconductor film 413, a second semiconductor film 414, and a third semiconductor film 415 can be sequentially grown on the wafer 411 using deposition equipment such as MOCVD.

The undoped film 412, the first semiconductor film 413, the second semiconductor film 414, and the third semiconductor film 415 can comprise a group II-VI compound or a group III-V compound, but is not limited thereto.

The undoped film 412 can be made of a semiconductor material that does not contain dopants. The undoped film 412 can be a seed layer that facilitates the growth of the first semiconductor film 413, the second semiconductor film 414, and the third semiconductor film 415 on the wafer 411. If the first semiconductor film 413, the second semiconductor film 414, and the third semiconductor film 415 are easily grown on the wafer 411, the undoped film 412 can be omitted.

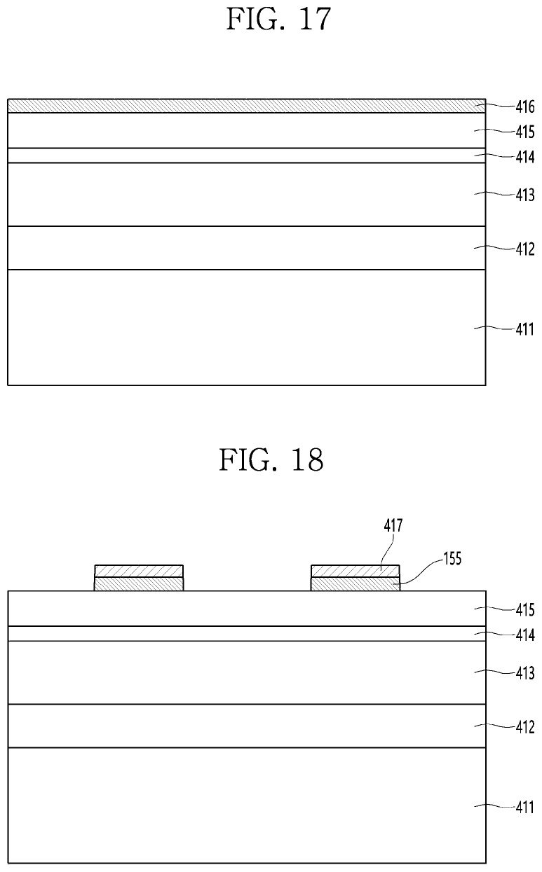

As shown in FIG. 17, a conductive film 416 can be formed on the third semiconductor film 415. The conductive film 416 is made of, for example, ITO, and can be deposited on the third semiconductor film 415 using sputtering equipment.

As shown in FIG. 18, after the photosensitive film is formed on the conductive film 416, the photosensitive film can be patterned to form a mask pattern 417. The mask pattern 417 can have a size corresponding to the size of the semiconductor light emitting device 150.

The conductive film 416 can be etched using the mask pattern 417 as a mask to form the second electrode 155.

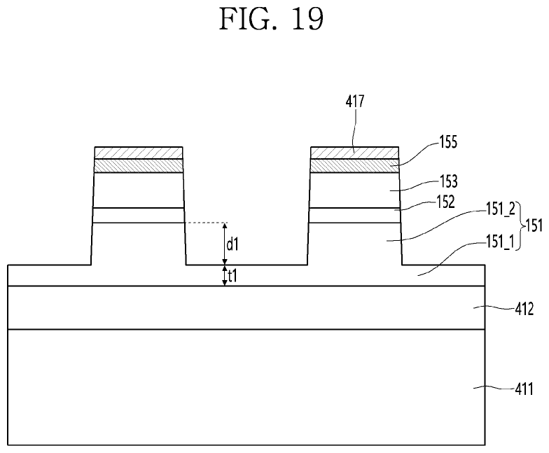

As shown in FIG. 19, an etching process can be performed using the mask pattern 417 as a mask. Through this etching process, the third semiconductor film 415 and the second semiconductor film 414 can be locally removed. Subsequently, the upper surface of the first semiconductor film 413 can be etched to a certain depth d1 by an additional etching process. In this instance, the remaining portion etched from the first semiconductor film 413 can have a thickness of t1.

Accordingly, the portion remaining after being removed from the third semiconductor film 415 can become the second conductivity type semiconductor layer 153, and the portion remaining after being removed from the second semiconductor film 414 can become the active layer 152. In addition, the remaining portion removed from the first semiconductor film 413 can become the first-second conductivity type semiconductor layer 151_2, and the unetched portion can become the first-first conductivity type semiconductor layer 151_1. Here, the first conductivity type semiconductor layer 151 can be composed of a first-first conductivity type semiconductor layer 151_1 and a first-second conductivity type semiconductor layer 151_2.

The etched depth d1 can be the same as the thickness (t2 in FIG. 14) of the first-second conductivity type semiconductor layer 151_2.

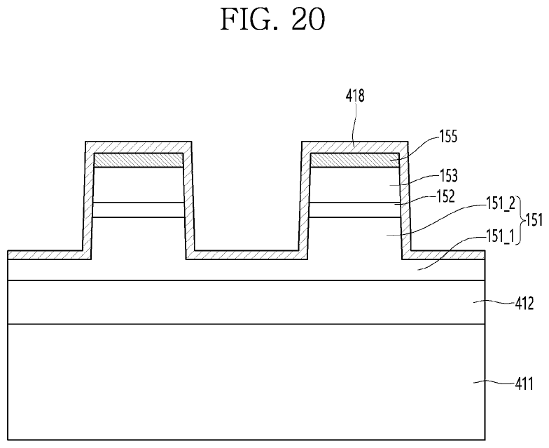

As shown in FIG. 20, the insulating film 418 can be formed on the entire area of the substrate 310 after the mask pattern 417 is removed.

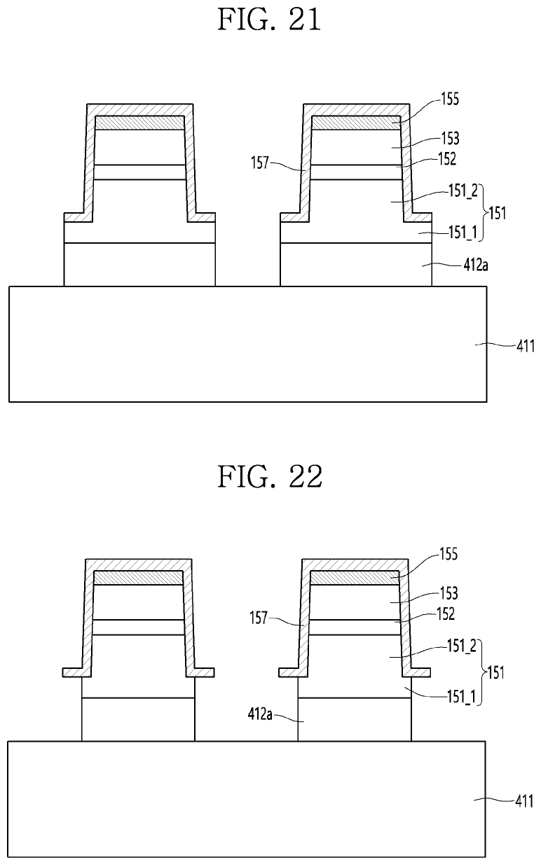

As shown in FIG. 21, the insulating film 418, the first-first conductivity type semiconductor layer 151_1, and the undoped film 412 located between the chips can be removed by etching between the chips. Here, the chip can define one semiconductor light emitting device 150. The undoped film 412 can be partially removed to form an undoped pattern 412a. The first-first conductivity type semiconductor layer 151_1 can be partially removed to form a first-first conductivity type semiconductor pattern. For convenience, the first-first conductivity type semiconductor pattern and the first-first conductivity type semiconductor layer 151_1 will not be distinguished. The insulating film 418 can be partially removed to form the protective layer 157.

The diameter of each of the first-first conductivity type semiconductor layer 151_1 and the undoped pattern 412a can be greater than the diameter of the first-second conductivity type semiconductor layer 151_2.

Meanwhile, the first conductivity type semiconductor layer 151, the active layer 152, and the second conductivity type semiconductor layer 153 can form a light emitting part.

As shown in FIG. 22, an additional etching process can be performed to overetch the first-first conductivity type semiconductor layer 151_1 and the undoped pattern 412a. Although the diameters of each of the first-first conductivity type semiconductor layer 151_1 and the undoped pattern 412a were reduced by the additional etching process, the diameter of each of the reduced first-first conductivity type semiconductor layer 151_1 and the undoped pattern 412a can still be greater than the diameter of the first-second conductivity type semiconductor layer 151_2.

The etching process shown in FIG. 22 can be an optional process and can be omitted.

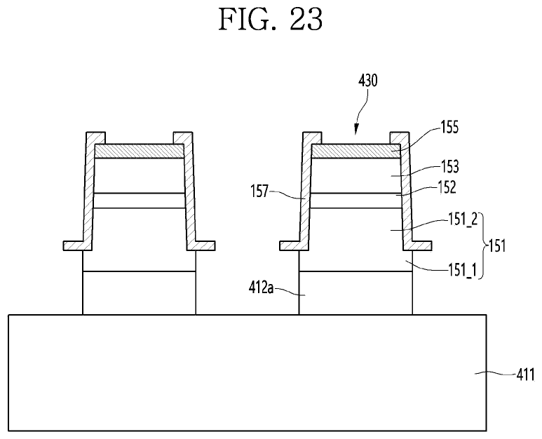

As shown in FIG. 23, a portion of the upper surface of the second electrode 155 can be exposed by removing the protective layer 157 on the upper side of the light emitting part 151 to 153. That is, the protective layer 157 can have an opening 430 corresponding to a portion of the second electrode 155.

In this way, the opening 430 can be formed in advance in the protective layer 157, so that the second wiring electrode (372 in FIG. 15) can be connected to the second electrode 155 of the semiconductor light emitting device 150 during manufacturing process of the display panel. Thus, the process can be shortened since there is no need for a separate process to form the opening 430 in the protective layer 157.

For example, when the semiconductor light emitting device 150 is self-assembled with the protective layer 157 formed on the second electrode 155, as shown in FIG. 15, after the second contact hole is formed in the second insulating layer 360, a process of forming an opening 430 by removing the protective layer 157 of the semiconductor light emitting device 150 corresponding to the second contact hole must be added.

After the semiconductor light emitting device 150 is assembled in the assembly hole (345 in FIG. 15) by self-assembly, if the second insulating layer 360 and the protective layer 157 are made of different materials when the second wiring electrode 372 is electrically connected to the second electrode 155 of the semiconductor light emitting device 150, the second contact hole must be formed under different process conditions and the opening 430 must be formed corresponding to the second contact hole, so that the process time may be increased. However, as shown in FIG. 23, during the manufacturing process of the semiconductor light emitting device 150, an opening 430 can be formed in advance in the protective layer 157 to expose the second electrode 155, thereby exposing the second electrode 155 during the manufacturing of the display panel. After the second contact hole is formed, the process of forming the opening 430 in the semiconductor light emitting device 150 is not necessary, thereby shortening the process time.

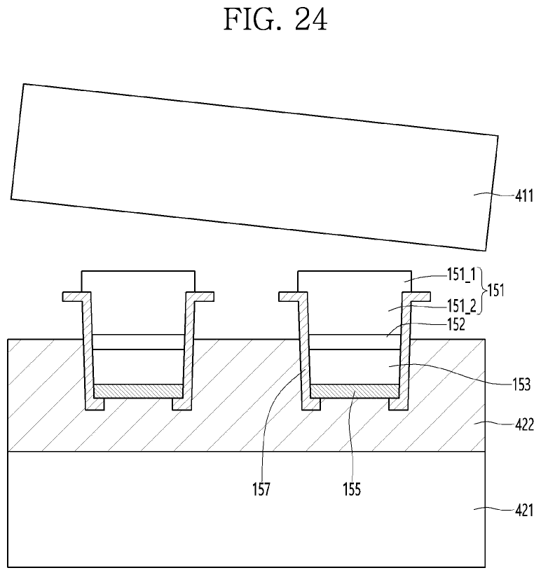

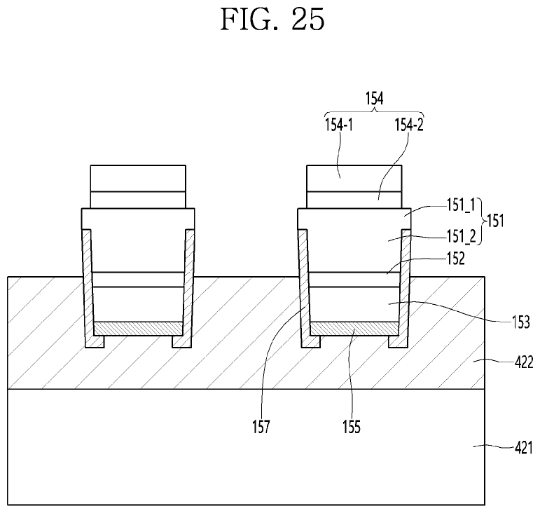

As shown in FIG. 24, the wafer 411 can be turned over and attached to the adhesive layer 422 on the transfer substrate 421. Subsequently, a laser lift-off (LLO) process can be performed to separate the semiconductor light emitting device 150 from the wafer 411 by irradiating a laser on the rear surface of the wafer 411.

When the wafer 411 is separated, the undoped pattern 412a can also be removed. Removal of the undoped pattern 412a can be optional and can be omitted.

By removing the undoped pattern 412a, the first-first conductivity type semiconductor layer 151_1 of the semiconductor light emitting device 150 can be exposed.

As shown in FIG. 25, the first electrode 154 can be formed on the first-first conductivity type semiconductor layer 151_1 of the semiconductor light emitting device 150. The first electrode 154 can comprise a magnetic layer 154_2 and a bonding layer 154_1.

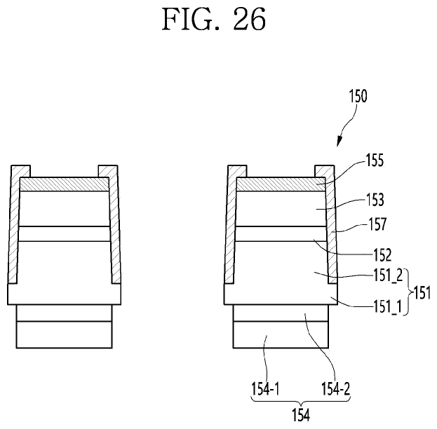

As shown in FIG. 26, a plurality of semiconductor light emitting devices 150 can be separated from the transfer substrate 421. For example, the transfer substrate 421 is immersed in an etchant to remove the adhesive layer 422, thereby allowing the plurality of semiconductor light emitting devices 150 to be separated from the transfer substrate 421. At this time, ultrasonic waves can be applied to the etchant to cause vibration for easier separation.

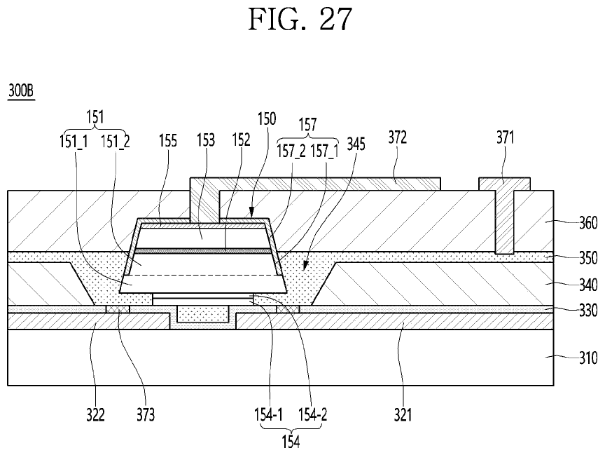

FIG. 27 is a cross-sectional view showing a display device according to a third embodiment.

The embodiment is the same as the second embodiment except for the second connection part 373. Accordingly, in the third embodiment, components having the same shape, structure, and/or function as those of the second embodiment are given the same reference numerals, and detailed descriptions are omitted.

Referring to FIG. 27, the display device 300B according to the third embodiment can comprise a substrate 310, a barrier rib 340, a semiconductor light emitting device 150, and a first connection part 350.

In addition, the display device 300B according to the third embodiment can comprise a first insulating layer 330, a first assembling wiring 321, a second assembling wiring 322, a second insulating layer 360, a first wiring electrode 371 and a second wiring electrode 372. The display device 300B according to the third embodiment can comprise more components than these.

In FIG. 27, the remaining components except for the second connection part 373 have been described in detail in the second embodiment, and detailed descriptions will be omitted.

The connection part 373 can electrically connect the first connection part 350 to at least one of the first assembling wiring 321 and the second assembling wiring 322 through the first insulating layer 330.

In FIG. 27, it is shown that two second connection parts 373 are provided to electrically connect the first connection part 350 to the first assembling wiring 321 and the second assembling wiring 322, respectively. A second connection part 373 may be provided to electrically connect the first connection part 350 to the first assembling wiring 321 or the second assembling wiring 322.

As an example, the first connection part 350 and the second connection part 373 can be made of different materials and can be formed through different processes. Specifically, after the semiconductor light emitting device 150 is assembled in the assembly hole 345, through an etching process, a first contact hole (or first opening) and a second contact hole (or second opening) can be formed to penetrate the first insulating layer 330 located in the assembly hole 345. Thereafter, a second connection part 373 can be formed in each of the first contact hole and the second contact hole, and the lower surface of the second connection part 373 can be in contact with the upper surface of the first assembling wiring 321 and upper surface of the second assembling wiring 322. Thereafter, the conductive liquid photosensitive material can be applied within the assembly hole 345 and on the barrier rib 340 and then cured by irradiation of ultraviolet light to form the first connection part 350. At this time, the first connection part 350 can be in contact with the second connection part 373 within the assembly hole 345.

As another example, the first connection part 350 and the second connection part 373 can be formed of the same material through a single process. Specifically, after the semiconductor light emitting device 150 is assembled in the assembly hole 345, through an etching process, a first contact hole (or first opening) and a second contact hole (or second opening) can be formed to penetrate the first insulating layer 330 located in the assembly hole 345. Thereafter, a conductive liquid photosensitive material can be applied in the assembly hole 345 and on the barrier rib 340 and then cured by irradiation of ultraviolet light, so that a second connection part 373 can be formed in the first contact hole and the second contact hole, the and the first connection part 350 can be formed within the assembly hole 345 and on the barrier rib 340. That is, the first connection part 350 and the second connection part 373 can be formed integrally through a single process.

In an embodiment, the first assembling wiring 321 and/or the second assembling wiring 322 can be used as the first wiring electrode 371. Accordingly, the negative (−) voltage supplied to the first assembling wiring 321 and/or the second assembling wiring 322 can be applied to the first electrode 154 of the semiconductor light emitting device 150 through the second connection part 373 and the first connection part 350. In addition, the positive (+) voltage supplied to the second wiring electrode 372 can be applied to the second electrode 155 of the semiconductor light emitting device 150. Accordingly, light with luminance corresponding to the current generated by positive (+) voltage and negative (−) voltage can be generated.

Although the first wire electrode 371 is shown in FIG. 27, when the first assembling wiring 321 and/or the second assembling wiring 322 are used as the first wire electrode 371, the first wire electrode 371 can be formed separately or may be omitted. When the first wiring electrode 371 is omitted, the first connection part 350 can be formed only within the assembly hole 345. That is, the first connection part 350 may not be formed on the barrier rib 340.

According to the third embodiment, after self-assembly, the first assembling wiring 321 and/or the second assembling wiring 322 can be electrically connected to the first connection part 350, and the first assembling wiring 321 and/or the second assembling wiring 322 can be used the first wiring electrode 371, so that there is no need to form the first wiring electrode 371 or the first contact hole shown in FIG. 27, thereby shortening the process time.

According to the third embodiment, since the first wiring electrode 371 does not need to be formed on the second insulating layer 360, the second wiring electrode 372 can be designed regardless of the layout of the first wiring electrode 371, so that the degree of freedom in designing the second wiring electrode 372 can be increased.

According to the third embodiment, the first assembling wiring 321 and/or the second assembling wiring 322 as well as the first wiring electrode 371 are disposed to supply the negative (−) voltage through more areas of the first connection part 350, so that current can flow more smoothly in the semiconductor light emitting device 150, thereby increasing light output to improve luminance.

FIG. 28 is a cross-sectional view showing a display device according to a fourth embodiment.

The embodiment is similar to the first to third embodiments except that the first assembling wiring 321 and the second assembling wiring 322 are disposed in different layers, and the lower side of the semiconductor light emitting device 150 is formed by at least one of the first assembling wiring 321 and the second assembling wiring 322. Accordingly, in the fourth embodiment, components having the same shape, structure, and/or function as those of the first to third embodiments are given the same reference numerals, and detailed descriptions are omitted.

Referring to FIG. 28, the display device 300C according to the fourth embodiment can comprise a substrate 310, a barrier rib 340, a semiconductor light emitting device 150, and a first connection part 350.

In addition, the display device 300C according to the fourth embodiment can comprise a first insulating layer 330, a first assembling wiring 321, a second assembling wiring 322, a second insulating layer 360, a first wiring electrode 371 and a second wiring electrode 372. The display device 300C according to the fourth embodiment can comprise more components than these.

The first assembling wiring 321 and the second assembling wiring 322 can be disposed on different layers. For example, the first assembling wiring 321 can be disposed on the first insulating layer 330, and the second assembling wiring 322 can be disposed under the first insulating layer 330.

In this instance, the first assembling wiring 321 can be used as the first wiring electrode 371. The first conductivity type semiconductor layer 151 of the semiconductor light emitting device 150, that is, the first-first conductivity type semiconductor layer 151_1, can be electrically connected to the first assembling wiring 321. As shown in FIG. 15, when the lowermost layer of the semiconductor light emitting device 150 is the second electrode 155, the second electrode 155 can be electrically connected to the first assembling wiring 321. For example, the semiconductor light emitting device 150 can be electrically connected to the first assembling wiring 321 by the bonding layer 154_1 of the second electrode 155 using a thermocompression process.

Meanwhile, since the first connection part 350 is formed in the assembly hole 345, the first connection part 350 can be in contact with the first assembling wiring 321.

The negative (−) voltage supplied to the first assembling wiring 321 can be applied directly from the first assembling wiring 321 to the second electrode 155 of the semiconductor light emitting device 150 or be applied to the side surface of the first-first conductivity type semiconductor layer 151_1 and the side surface of the second electrode 155 of the semiconductor light emitting device 150 through the first connection part 350.

Therefore, according to the fourth embodiment, the first assembling wiring 321 can be used as the first wiring electrode 371, and as shown in FIG. 28, there is no need to separately form the first wiring electrode 371 and the first contact hole, thereby shortening the process time.

According to the fourth embodiment, the first wiring electrode 371 does not need to be formed on the second insulating layer 360. Therefore, since the second wiring electrode 372 can be designed regardless of the layout of the first wiring electrode 371, the degree of freedom in designing the second wiring electrode 372 can be increased.

According to the fourth embodiment, the first assembling wiring 321 and/or the second assembling wiring 322 as well as the first wiring electrode 371 are disposed to supply the negative (−) voltage through more areas of the first connection part 350, so that current can flow more smoothly in the semiconductor light emitting device 150, thereby increasing light output to improve luminance.

According to the fourth embodiment, the lower side surface of the semiconductor light emitting device 150 can be directly in contact with the first assembling wiring 321 to further reduce line resistance or contact resistance, so that luminance can be improved by increasing light output by allowing current to flow more smoothly in the semiconductor light emitting device 150.

Meanwhile, although not shown, the first assembling wiring 321 can be disposed under the first insulating layer 330, and the second assembling wiring 322 can be disposed on the first insulating layer 330. In this instance, the lower side surface of the semiconductor light emitting device 150 can be in contact with the second assembling wiring 322.

Meanwhile, although not shown, a third connection part can be provided. As shown in FIG. 13, the third connection part can be electrically connected to at least one or more of the first assembling wiring 321 and the second assembling wiring 322 through the second insulating layer 360, the first connection part 350, the barrier rib 340, and the first insulating layer 330. In this instance, the assembling wiring connected to the third connection part can be used as a wiring electrode for emitting light from the semiconductor light emitting device 150. For example, a positive (+) voltage can be applied to the second conductivity type semiconductor layer 153 of the semiconductor light emitting device 150 through the second wiring electrode 372. For example, a negative (−) voltage can be applied to the first conductivity type semiconductor layer 151 of the semiconductor light emitting device 150 through the third connection part and the first connection part 350 through the assembling wiring 321 and 322. Accordingly, light having luminance corresponding to the current flowing by the negative (−) voltage and the positive (−) voltage can be generated from the semiconductor light emitting device 150.

The above detailed description should not be construed as restrictive in any respect and should be considered illustrative. The scope of the embodiments should be determined by reasonable interpretation of the appended claims, and all changes within the equivalent scope of the embodiments are included in the scope of the embodiments.

### INDUSTRIAL APPLICABILITY

The embodiment can be adopted in the field of displays that display images or information.

The embodiment can be adopted in the field of displays that display images or information using semiconductor light emitting devices.

The embodiment can be adopted in the field of displays that display images or information using micro-level or nano-level semiconductor light emitting devices.

1. A display device, comprising:
a substrate;
a barrier rib having an assembly hole on the substrate;
a semiconductor light emitting device in the assembly hole; and
a first connection part disposed in the assembly hole and on the barrier rib and electrically connected to a side surface of the semiconductor light emitting device,
wherein the semiconductor light emitting device comprises:
a first conductivity type semiconductor layer comprising a first-first conductivity type semiconductor layer and a first-second conductivity type semiconductor layer on the first-first conductivity type semiconductor layer;
an active layer on the first-second conductivity type semiconductor layer;
a second conductive semiconductor layer on the active layer; and
a protective layer,
wherein the first-first conductivity type semiconductor layer comprises:
a first region having an area equal to that of the first-second conductivity type semiconductor layer; and
a second region surrounding the first region and,
wherein the protective layer surrounds a side surface of the first-second conductivity type semiconductor layer and vertically overlaps with the second region of the first-first conductivity type semiconductor layer.

2. The display device of claim 1, wherein the first connection part comprises a conductive liquid photosensitive material.

3. The display device of claim 1, wherein
the protective layer surrounds a side surface of the active layer, and a side surface of the second conductivity type semiconductor layer.

4. The display device of claim 3, wherein the first connection part is in contact with the side surface of the first-first semiconductor light emitting device along a perimeter of a side surface of the first-first conductivity type semiconductor layer.

5. The display device of claim 3, wherein a first thickness of the first-first conductivity type semiconductor layer is smaller than a second thickness of the first-second conductivity type semiconductor layer.

6. The display device of claim 3, wherein an area around the side surface of the first-first conductivity type semiconductor layer is greater than an area of the lower surface of the first-first conductivity type semiconductor layer.

7. The display device of claim 3, wherein a first diameter of the first-first conductivity type semiconductor layer is greater than a second diameter of the first-second conductivity type semiconductor layer.

8. The display device of claim 3, wherein
the first region vertically overlapping with the first-second conductivity type semiconductor layer.

9. The display device of claim 3, comprising:
a first insulating layer between the substrate and the barrier rib;
a first assembly wiring and a second assembly wiring partially overlapping the assembly hole;
a second insulating layer on the first connection part and the semiconductor light emitting device; and
a second wiring electrode electrically connected to the second conductive semiconductor layer through the second insulating layer.

10. The display device of claim 9, comprising:
a first wiring electrode electrically connected to the first connection part through the second insulating layer.

11. The display device of claim 9, wherein the first assembly wiring and the second assembly wiring are disposed in the same layer.

12. The display device of claim 11, comprising:
a second connection part electrically connecting the first connection part to at least one of the first assembly wiring and the second assembly wiring through the first insulating layer, and
the at least one assembling wiring is a first wiring electrode.

13. The display device of claim 9, wherein the first assembly wiring and the second assembly wiring are arranged in different layers.

14. The display device of claim 13, wherein one of the first assembly wiring and the second assembly wiring is electrically connected to the first-first conductivity type semiconductor layer.

15. The display device of claim 14, wherein one of the first assembly wiring and the second assembly wiring is in contact with the first connection part.

16. The display device of claim 3, wherein the protective layer comprises;
a first protective layer in contact with the first connection part; and
a second protective layer in contact with the second insulating layer.

17. The display device of claim 1, wherein an upper side of the semiconductor light emitting device protrudes upward from an upper surface of the first connection part.

18. The display device of claim 1, wherein the first connection part is configured to contact a side surface of the first-first conductivity type semiconductor layer.

19. The display device of claim 1, wherein the semiconductor light emitting device comprises:
a first electrode under the first conductivity type semiconductor layer and
a second electrode on the second conductivity type semiconductor layer,
wherein the first connection part is configured to contact a side surface of the first electrode.

20. A display device, comprising:
a substrate;
a barrier rib having an assembly hole on the substrate;
a semiconductor light emitting device in the assembly hole; and
a first connection part comprising a first region disposed in the assembly hole and a second region on an upper surface of the barrier rib and electrically connected to a side surface of the semiconductor light emitting device; and
a first wiring electrode electrically connected to the second region of the first connection part.
